(19) United States
(12) Patent Application Publication
(10) Pub. No.: US 2007/0297216 A1
(43) Pub. Date: Dec. 27, 2007

(54) SELF-ASSEMBLY OF MOLECULAR DEVICES

(75) Inventors: James M. Tour, Bellaire, TX (US); Jiping Yang, Houston, TX (US); Philipp Harder, Hauenstein (DE); David L. Allara, State College, PA (US); Paul Weiss, State College, PA (US); Long Cheng, Sunnyvale, CA (US); Paul D. Franzon, Holly Springs, NC (US); David Nackashi, Raleigh, NC (US)

Correspondence Address: WINSTEAD PC, P.O. BOX 50784, DALLAS, TX, 75201, US

(73) Assignees: William Marsh Rice University, Houston, TX (US); Penn State Research Foundation

(21) Appl. No.: 11/740,170

(22) Filed: Apr. 25, 2007

Related U.S. Application Data
(63) Continuation-in-part of application No. 10/090,211, filed on Mar. 4, 2002, now abandoned.
(63) Continuation-in-part of application No. 11/190,525, filed on Jul. 27, 2005.
(60) Provisional application No. 60/272,895, filed on Mar. 2, 2001.

(51) Int. Cl. G11C 11/56; B05D 1/04; C25D 5/00; H01L 45/00; H01L 21/62; C25D 5/10

(52) U.S. Cl. 365/151; 205/170; 205/80; 257/4; 427/472; 438/139; 977/750; 977/709

(57) ABSTRACT

A method for selectively assembling a molecular device on a substrate comprises contacting the first substrate with a solution containing molecular devices; impeding bonding of the molecular devices to the substrate such that application of a voltage potential to the substrate results in assembly of the molecular device on the substrate at a rate that is at least 1.5 times the rate of assembly of the molecular device on a voltage-neutral substrate; and applying a voltage potential to the substrate so as to cause the molecular devices to assemble on the substrate. A nanoscale computing device is described that includes a substrate, a pair of conductive input/output electrodes carried on this substrate and disposed in spaced-apart relationship and a substantially disordered assembly of nanowires formed on the substrate in a region between the electrodes, thereby forming at least one programmable conductive pathway between the pair of electrodes.

### CROSS-REFERENCE TO RELATED APPLICATIONS

This application is a continuation-in-part of U.S. application Ser. No. 10/090,211, filed Mar. 4, 2002, which claims benefit of priority to U.S. Provisional Application No. 60/272,895 filed Mar. 2, 2001. This application is also a continuation-in-part of U.S. application Ser. No. 11/190,525, filed on Jul. 27, 2005, which claims benefit of priority to PCT Application No. WO 2004/068,497, filed Jan. 28, 2004, which in turn claims benefit of priority to U.S. Provisional Application No. 60/443,148, filed on Jan. 28, 2003. All priority documents are incorporated herein by reference in their entirety.

### STATEMENT REGARDING FEDERALLY SPONSORED RESEARCH OR DEVELOPMENT

This work was supported by the Defense Advanced Research Projects Agency (DARPA), the Office of Naval Research (ONR), and the National Science Foundation (NSF, NSR-DMR-0073046).

### TECHNICAL FIELD OF THE INVENTION

The present invention relates generally to a method for assembling molecular devices. More particularly, the present invention relates to the construction of devices useful in electronic circuitry including computer logic circuit devices.

### BACKGROUND OF THE INVENTION

Molecular scale electronics is an emerging field that proposes the use of single molecules or small groups of molecules to function as the key components in computational devices. The concept is based on the use of molecules or groups of molecules that transmit current either linearly or non-linearly when subjected to a voltage potential. In particular, molecules or groups of molecules that have linear I/V curves can resemble wires and are termed “molecular wires,” or sometimes “molewires.” Molecules or groups of molecules that have non-linear I/V curves can resemble other types of electronic devices and are therefore termed “molecular components,” “molecular switches,” or sometimes “moleswitches.” The term “molecular device” will be used herein to denote all such molecular-scale conducting devices.

It is becoming more widely accepted that, given a sufficient selection of operable molecular devices, molecular-scale computers could be constructed using principles similar to those used to construct conventional, semiconductor-based computers. In addition to the substantial size reductions that would result, the response times of molecular devices can be in the range of femto-seconds, while the fastest present devices operate in the nanosecond regime. Thus, a significant increase in speed may be attainable, particularly if other circuit elements do not limit operational performance. Different substituent groups can be used to provide molecular devices with a variety of electronic properties, such as negative differential resistance (NDR), molecular memory capability, and molecule-scale switching behavior.

An ongoing challenge in implementing molecular scale electronics has been the search for techniques that will allow the controlled assembly of molecular devices. While self-assembled monolayers (SAMs) of conjugated thiols on Au have drawn considerable attention due to their potential use in molecular electronics and have been shown to serve as molecular device components, controlled, precise placement of such SAMs in a manner that would allow them to function as molecular devices has not heretofore been possible. The success of molecular computing depends in part on the precise placement of molecular device components on a patterned substrate. Thus, in some instances, it becomes crucially important to accurately direct the assembly of the components onto specific electrodes. Conventional chemical self-assembly techniques cannot furnish such selectivity.

Several groups have reported successful electrochemical oxidative adsorption of alkane thiols on various surfaces, such as Au, Ag, and Hg. Recently, Hsueh and co-workers reported the electrochemical oxidation of alkylthiosulfate (R—S₂0₃-) on Au electrodes at +1200 mV (versus Ag/AgNO₃). Monolayer formation took place preferentially on the biased Au electrodes, while the electrodes that were not biased experienced slower adsorption. However, the thiosulfate method produces alkylsulfide radicals and has been demonstrated so far only with simple n-alkane derivatives.

Potential-enhanced self-assembly of certain alkanethiols that are not molecular devices is also known, but, until now, no one has yet discovered how to effect controlled, selective assembly of molecular devices on designated substrates under mild electric potentials. It has been observed that thiol-based molecules assemble almost equally rapidly on non-charged surfaces as on charged surfaces. The similar behavior of charged and non-charged surfaces has heretofore made it impossible to use voltage-assisted assembly to apply molecular device layers in a controlled or targeted manner.

It is recognized that the construction of a practical molecular or nanoscale computer will require switches and their related interconnect technologies to behave as large-scale diverse logic, with input/output leads scaled to molecular dimensions.

It is well known to those of ordinary skill in the art that semiconductor devices are constructed using a “top-down” approach that employs a variety of semiconductor lithographic and etch techniques to pattern a substrate and this approach has become increasingly challenging to apply as feature sizes decrease. In particular, at the nanometer scale, the electronic properties of semiconductor structures fabricated using conventional lithographic process are increasingly difficult to control. By contrast, using a “bottom-up” approach, the present invention relates to an approach in which functional molecules and other nanoscale components are assembled, in some cases on discontinuous films, and then interconnected (“wired up”) with nanotubes or nanowires for the purpose of constructing functional nanoscale computer devices.

Hence, there is still a need for methods that allow small, i.e. molecular scale, devices to be assembled quickly and accurately and in a controlled or targeted manner. A preferred method would allow the application of desired layers without undue expense.

### BRIEF SUMMARY OF THE INVENTION

The present invention solves the problems associated with the prior art inasmuch as it allows controlled, selective assembly of molecular devices on metal electrodes and thus provides a method for assembling molecular scale devices quickly and accurately and without undue expense.

In some aspects, the present invention relates to a method using a small voltage potential to drive the free thiols or thiolates to assemble on a metal surface. By impeding the rate of formation of thiolates in combination with the use of a voltage potential, sufficient differentiation between adjacent surfaces can be achieved to allow selective assembly of molecular devices.

In other aspects, the present invention provides a nanoscale computing device that includes a substrate, a pair of conductive input/output electrodes carried on this substrate and disposed in spaced-apart relationship and a substantially disordered assembly of nanowires formed on the substrate in a region between the electrodes, thereby forming at least one programmable conductive pathway between the pair of electrodes.

The foregoing has outlined rather broadly the features of the present invention in order that the detailed description of the invention that follows may be better understood. Additional features and advantages of the invention will be described hereinafter which form the subject of the claims of the invention.

### BRIEF DESCRIPTION OF THE DRAWINGS

For a detailed understanding of the present invention, reference is made to the accompanying Figures, wherein:

FIG. 1 illustrates six exemplary molecules that can be selectively assembled according to the present invention;

FIG. 2 is a schematic overview of the steps involved in a preferred embodiment of the present method;

FIG. 3 is a plot of the growth rate of a layer of molecule (a) on an Au surface in the absence of potential;

FIG. 4 is plot showing cyclic voltammograms of a gold electrode in a solution of KCl/K₃[Fe(CN)₆] (0.1 M/1 mM);

FIG. 5 is a plot showing cyclic voltammograms of a gold electrode covered with molecular device (a) of FIG. 1;

FIG. 6 is a plot showing cyclic voltammograms of a platinum electrode covered with molecular device (a) of FIG. 1;

FIG. 7 is a comparison between a layer of molecular device (a) in a KBr matrix (top) and monolayers on a gold electrode that were grown electrochemically or adsorbed from solution without potential;

FIG. 8 illustrates six exemplary molecules that can be selectively assembled according to an alternate embodiment of the present invention; and

FIGS. 9-14 are illustrations of various molecules that can be used in the methods of the present invention to form molecular devices.

FIG. 21 is a scanning electron microscope image of a NanoCell nanoscale memory device in accordance with one embodiment of the invention;

FIG. 22 is a scanning electron microscope image of a nanowire disposed within the NanoCell of FIG. 21;

FIG. 23 is a plot showing the current voltage I(V) characteristics between juxtaposed leads of the NanoCell of FIG. 21;

FIG. 24 is a molecular diagram of a compound applied to the active area of the NanoCell of FIG. 21;

FIG. 25a is a diagram showing a portion of a molecularly-encapsulated nanowire during a first phase of its preparation;

FIG. 25b is a diagram showing the portion of a molecularly-encapsulated nanowire during a second phase of its preparation;

FIG. 25c is a schematic illustration of a plurality of molecularly-encapsulated nanowires applied onto a discontinuous conductive film on a NanoCell substrate;

FIG. 26 is a plot showing the I(V) characteristics of the NanoCell of FIG. 21 after being subjected to programming voltage pulses; and

FIG. 27 is a plot showing the I(V) characteristics of the NanoCell of FIG. 21 before and after being subjected to voltage set-pulses.

### DETAILED DESCRIPTION OF THE INVENTION

It has been discovered that molecular devices can be selectively assembled on desired substrates quickly and with a high degree of precision. According to a preferred embodiment of the present invention, the difference in the rates of assembly of a given molecular device on a given metal substrate can be used to control the placement of the molecular device. More particularly, applicants have discovered a technique for slowing the assembly of molecular devices on a non-charged surface. As a result, the use of a small voltage sufficiently accelerates the rate of assembly that the present methods can be used to selectively assemble molecular devices on substrates that are at least as close together as 0.3 μm.

According to one aspect of the present invention, thiol-terminated molecular devices are deprotonated in a basic solution, thereby forming thiolates. Thiolates assemble on charged and non-charged surfaces, but the rate of assembly on selected surfaces is greatly enhanced by the application of a voltage potential to those surfaces. According to another embodiment, free thiols are formed from protected molecular device molecules in an acidic solution. If the rate of formation of the free thiol is slowed sufficiently, a layer can be selectively formed by enhancing the rate of deposition on a selected surface. While the bulk of the discussion below is presented in terms of the basic solution technique, the concepts set out herein are intended to include not only acidic and basic solution schemes, but any other scheme by which the rate of assembly of molecular device molecules can be impeded and selectively enhanced so as to allow for selective application.

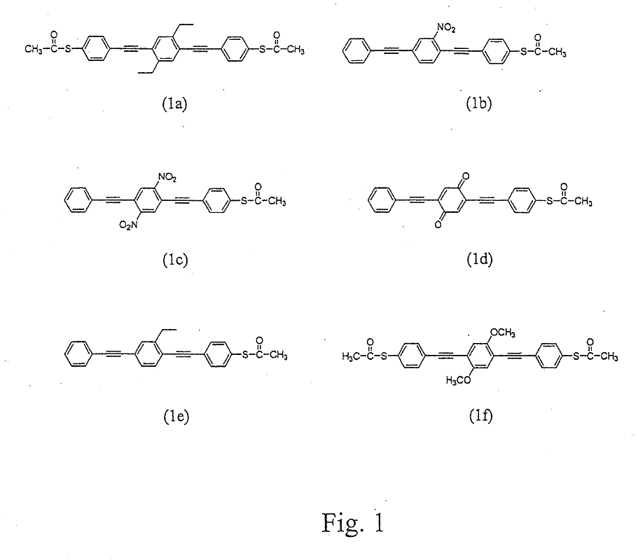

Referring initially to FIG. 1, several thioacetates that are suitable for use in the present invention are shown. While the molecules illustrated in FIG. 1 are known to be effective in the present process, the present invention is not limited to the molecules shown in FIG. 1. Additional suitable molecular device molecules, along with schemes for making them, can be found in Tour, J. M.; Rawlett, A. M.; Kozaki, M.; Yao, Y.; Jagessar, R. C.; Dirk, S. M.; Price, D. W.; Reed, M. A.; Zhou, C.; Chen J.; Wand, W.; and Campbell, I. Chem. Eur. J. 2001, 7, No. 23, 5118-5134, which is incorporated herein by reference in its entirety. In addition, any of the molecular devices taught in Chen, J.; Reed, M. A.; Rawlett, A. M.; Tour, J. M. Science 1999, 286, 1550, Chen, J.; Wang, W.; Reed, M. A.; Rawlett, A. M.; Price, D. W.; Tour, J. M. Appl. Phys. Lett. 2000, 77, 1224, or Bumm, L. A.; Arnold, J. J.; Cygan, M. T.; Dunbar, T. D.; Burgin, T. P.; Jones, L., II; Allara, D. L.; Tour, J. M.; Weiss, P. S. Science 1996, 271, 1705, all of which are incorporated herein by reference, can be used in the present invention.

Specifically, molecular devices that are suitable for use with the present invention include pi-conjugated aromatics and in particular, protected thiol-terminated oligo(phenylene ethynylene)s, are preferred for use as molecular devices.

According to the present invention, the thiol-terminated molecular devices need to include on each thiol a group that can be removed by the application of a desired chemical or electrochemical stimulus. It has been discovered that the presence of the protecting group sufficiently slows the rate of formation of thiolate in a basic solution, or thiol in an acidic solution, that the voltage applied to an electrode surface will cause the molecules to assemble on that surface significantly faster than on a non-charged surface in the same solution. Furthermore, a pH neutral solution could be used in a similar scheme, wherein the thiol protecting group is removed electrochemically,

In one preferred embodiment, the stimulus is a voltage potential and the protecting group is selected from the protecting groups identified in Greene, T.; Wuts, P. Protective groups in Organic Synthesis, 3d ed. (1999), which is incorporated herein by reference. Particularly preferred are the protecting groups listed in chapter six of that reference, including thioethers, S-diphenylmethyl thioethers, substituted S-diphenylmethyl thioethers, and S-triphenylmethyl thioethers, substituted S-methyl derivatives, substituted S-ethyl derivatives, silyl thioethers, thioesters, thiocarbonate derivatives, and thiocarbamate derivatives. Also particularly preferred are thioacetates, sometimes called thioacetyl groups or thiolacetates, also known by the formula SCOCH₃. A thiol-terminated molecular device protected in this manner will be referred to herein as a “monolayer precursor.” The exemplary molecules shown in FIG. 1 are S-acetyl-oligo(phenylene ethynylene)s.

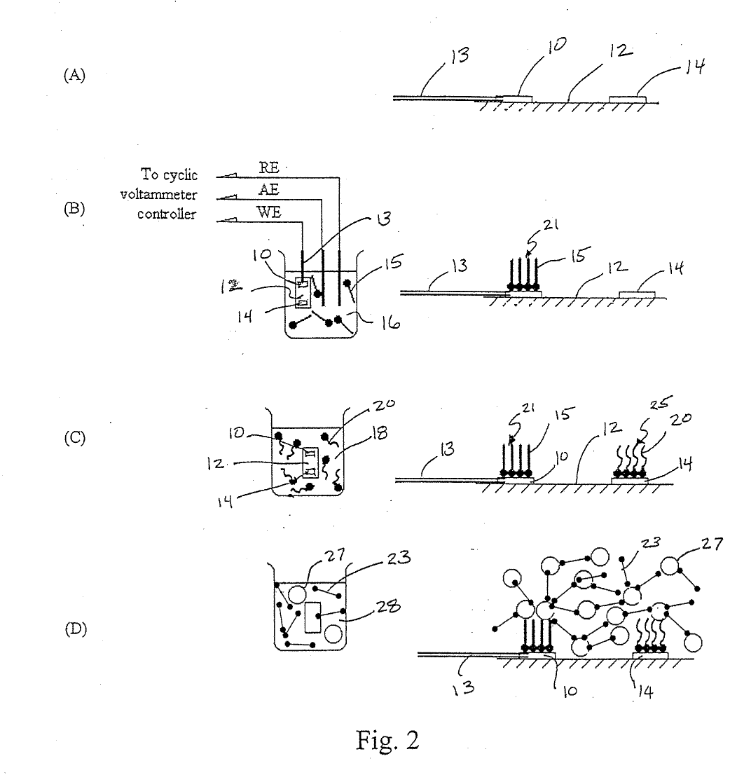

Referring now to FIG. 2, the present method can be used to selectively assemble a first monolayer on at least one substrate 10, which may be affixed to a base 12 adjacent to a second substrate 14. One preferred embodiment of the present method includes electrically connecting a conducting lead 13 to the first substrate 10, as shown in FIG. 2(A). With lead 13 in place, base 12, carrying substrates 10 and 14, can be placed in a solution 16 containing the desired monolayer precursor molecules 15, as shown in FIG. 2(B).

A voltage potential is applied to the first substrate 10 via lead 13. In FIG. 2(B), lead 13 is identified as the working electrode (WE), and is used in a conventional manner in conjunction with a reference electrode (RE) and an auxiliary electrode (AE). It is not necessary to wait until the substrate 10 is submerged in the solution 16 to apply the voltage. Application of the voltage causes a layer of the desired precursor molecules 15 to assemble into a monolayer 21 on the surface of substrate 10.

According to the present invention and as described above, the monolayer precursor molecules 15 each include a protecting group that prevents or impedes rapid assembly of the monolayer on the substrate in the absence of a potential to draw the low concentration of free thiol or thiolate to the surface. Depending on the precursor used, solution 16 can be either an acidic or basic solution. Without being bound by the following, it is speculated that the presence of a base causes the protecting groups on certain monolayer precursor molecules to disassociate from the precursor molecules. The deprotected thiol groups on the precursor molecules are then deprotonated by the base, forming charged thiolate groups. These charged thiolate groups, in turn, are attracted to the positively charged electrode (substrate 10) and assemble there. Similarly, we have discovered the methods of the present invention can be used advantageously in acidic solutions, albeit via a different mechanism. In acidic solutions, the terminal groups on the molecular device precursors do not form thiolates, and instead form free thiols, which, like thiolates, are advantageously drawn to the charged surface.

It has been discovered that even though some monolayer precursors molecules may assemble on second substrate 14 while the layer is assembling on first substrate 10, the disparity between the rates of assembly on the charged and non-charged substrates is great enough to allow selective assembly. More particularly, the use of a protecting groups on the precursor prevents the thiol groups from assembling and impedes formation of thiolate groups, while the application of a voltage potential to first substrate 10 accelerates the rate of assembly on substrate 10. The combination of these effects separates the rates of assembly on the two substrates to such a degree that the amount of monolayer that assembles on second substrate 14 during the time required to assemble a desired layer on first substrate 10 is relatively insignificant. For example, in some systems, the acetate-impeded, potential-assisted assembly is one to two orders of magnitude faster than acetate-impeded, non-potential-assisted assembly. The overall rate of assembly is partially dependent on molecular structure. According to the present invention, similar differentiation can be also achieved when the protecting group is other than an acetate group.

Referring still to FIG. 2, following the selective placement of a monolayer on one or more of the substrates 10, the base 12 can be placed in a second solution 18 containing second precursor molecules 20. The second precursor is preferably but not necessarily a molecular device. Also, the second precursor may be protected or not protected, and the assembly of the second precursor into a monolayer can be voltage-assisted or not. Because the surface of the first substrate is already covered with the first monolayer 15, molecules of the second precursor do not rapidly bond to substrate 10. It is an advantage of the present invention that the deprotected, deprotonated thiolate of the present invention generally shows relatively slow tendency to displace an already-formed monolayer. Once a second monolayer 25 has formed on substrate 14, base 12 can be removed from solution 18 and placed in a third solution 28, which may contain precursors 23 for additional molecular devices and/or metal nanoparticles 27, such as are known in the art. Hence, it is possible to apply different molecular device species sequentially without affecting previously applied layers. By applying different molecular devices sequentially using the present methods, it becomes possible to construct a complex device. In a particularly preferred embodiment, precursors 23 comprise conjugated molecules that have a thiol on each end, such as could be generated from FIG. 1(a).

It has further been discovered that the application of a voltage potential to one substrate affects only those precursor molecules that are very close to that substrate. Thus, the present method has been used to selectively produce a monolayer on one of two substrates that are separated by gaps as small as 0.3 μm and it is expected that substrate differentiation could be achieved across even smaller distances, with the lower limit being defined only by the limits of lithography or other types of patterning, such as electron beam. Hence, the present method is suitable for use in the construction of micro- or nano-electronic devices.

Another advantage of the present invention is that it allows the rapid assembly rate associated with thiolate or thiol assembly without requiring storage or handling of thiolate or thiol solutions. Specifically, thiolates and aromatic thiols are unstable against oxidation, while thioacetates can be stored for extended periods in air without degradation. According to the present invention, the convenience of having a thioacetate stock solution can be combined with a rapid adsorption.

It has further been discovered that molecular device components containing electron-donating groups assemble faster than those with electron-withdrawing groups. For example, using the present invention, one can deposit molecules with electron donating groups, e.g. FIG. 1(f), on one electrode, followed by the deposition of molecules with electron withdrawing groups, e.g. FIG. 1(c), on another electrode. The formation of different layers on adjacent substrates is illustrated schematically in FIG. 2. By bridging the two molecular wire-decorated electrodes with a conducting material, one may observe device behavior.

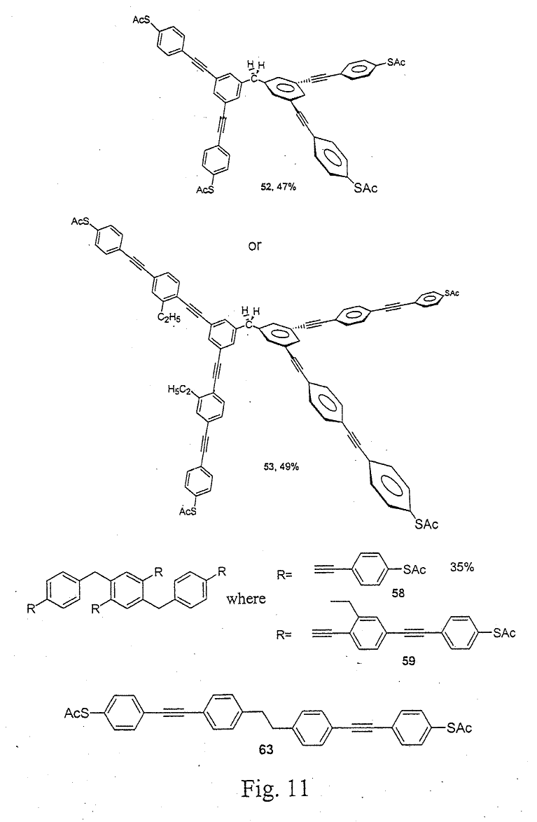

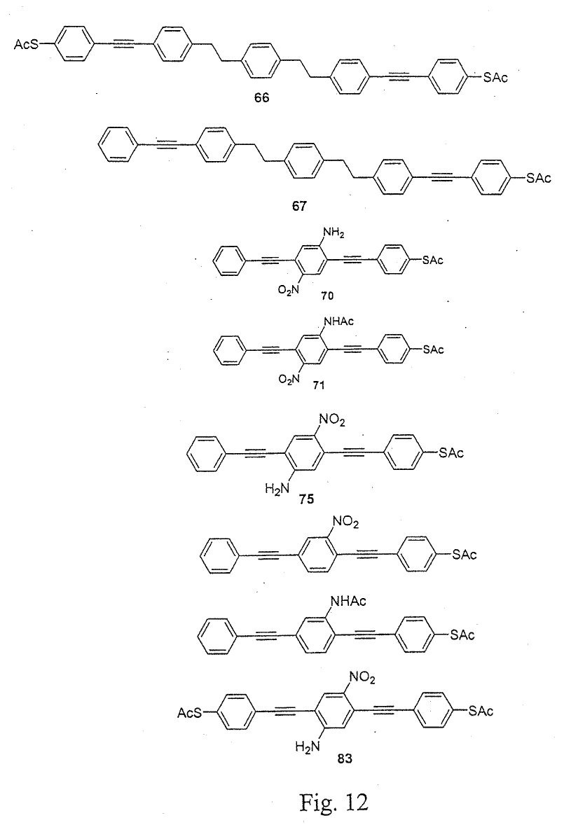

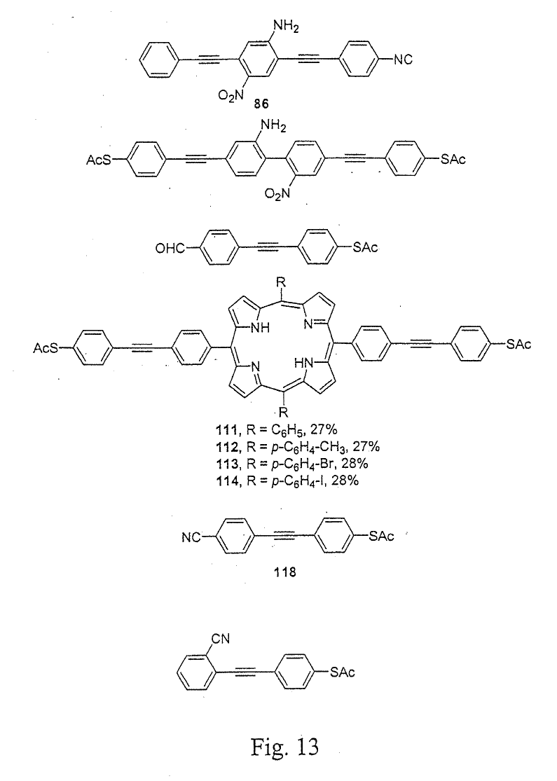

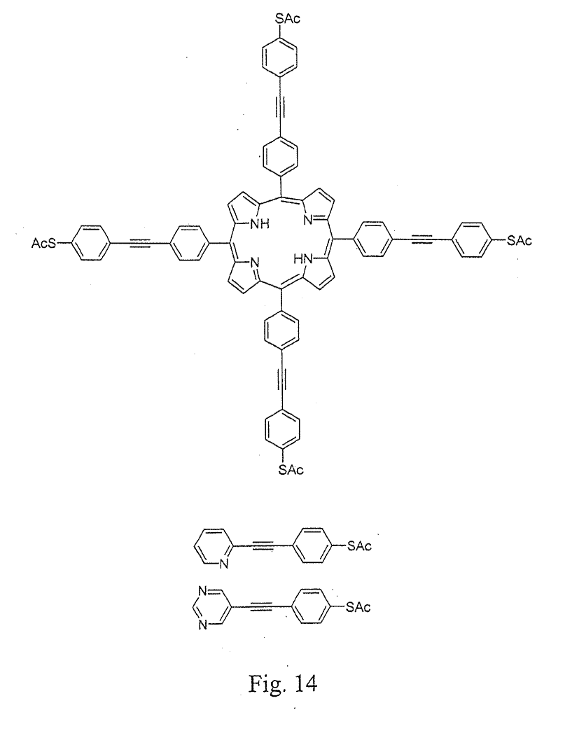

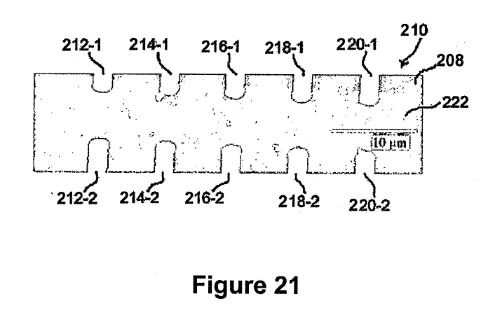

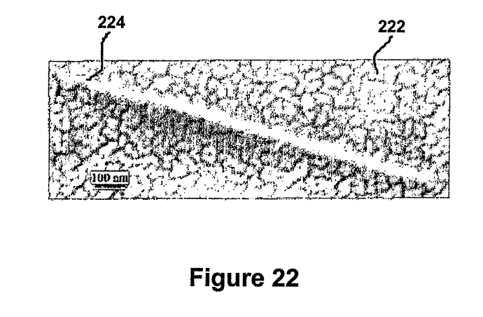

One skilled in the art of molecular devices will recognize that the principles of the present invention are applicable to systems that include a variety of molecular device molecules. The molecular devices that can be applied or selectively applied using the present techniques include but are not limited to the various molecules shown in FIGS. 9-14.

The concepts of the present invention are useful with metal substrates generally, and more particularly with the coinage metals or late transition metals, including but not limited to gold, palladium, silver, copper and platinum.

Similarly, the metal-bonding terminus of the present invention can be other than sulfur. For example, selenium and tellurium can be substituted for the sulphur. Hence, the present invention is not limited to thiol-terminated molecular devices, but also includes selenol and tellurol, as is known in the art. See, for example, Reinerth, W. A.; Tour, J. M. “Protecting Groups for Organoselenium Compounds,” J. Org. Chem. 1998, 63, 2397-2400.

Solvents that are useful in the present invention include but are not limited to alcohols, water, and any nonreactive organic solvent, or combination thereof. Similarly, the electrolyte can be any soluble ionic salt that is not corrosive to the electrode.

The identity and orientation of the molecular device components on the metal surface is another important issue for the present electrochemical assembly technique. The average orientation of compound (a) on the surface can be derived from the relative intensities of a pair of IR absorption bands that correspond to molecular vibrations that are either parallel or perpendicular to the oligo(phenylene ethynylene) axis. A random orientation would give the same relative band intensities in both the external reflection IR spectrum of the monolayer and the transmission spectrum of the bulk sample. In contrast, an ordered orientation of the molecules will show an increased intensity of the parallel vibrations. If the molecules tilt towards the surface (angle >54.7°) the perpendicular bands will dominate the monolayer spectrum. IR spectra of substrates selectively coated according to the present invention confirm that monolayers are present. Layers deposited according the present technique have structures that are similar to the structures of layers deposited in a conventional, non-potential assisted manner.

The rate of assembly of thiolate-terminated oligo(phenylene ethylene) molecular device components under electric potential is greatly enhanced. A low thiolate concentration can be maintained by the in situ deprotection of some part of a thioacetate derivative stock solution. The accelerated adsorption on positively charged electrodes, combined with a low thiolate concentration in solution, makes it possible to selectively deposit molecules onto specific electrodes. The molecular orientation in the SAM made under electric potential is similar to the SAM made by conventional self-assembly technique. The in-situ cleavage of the thioacetate derivative reduces the problems with the instability of the thiolate or thiol solution. The thioacetate itself adsorbs only slowly on metal surfaces. Similar rate differentiation and selectivity can be obtained using a basic solution. The acid solution techniques is preferred for some molecular devices as it results in a more intact layer.

### EXAMPLES

The following Example are intended to illustrate the efficacy of certain embodiments of the invention and are not intended to be limiting in any way.

Self-Assembly of Thiolates on Gold Using Base Deprotection.

Materials.

Ethanol (Pharmco Products Inc., 200 proof, USP Grade) was degassed with nitrogen prior to use. THF (Aldrich) was freshly distilled from Na/benzophenone under an atmosphere of nitrogen, and used immediately. Tetrabutylammonium tetrafluoroborate was purchased from Aldrich and used without further purification. The syntheses of the oligo(phenylene ethynylene)s are known, and are described in the references identified above. Au substrates were prepared by the sequential deposition of Cr (50 nm) and Au (120 nm) onto a clean single crystal Si wafer. Metal depositions were carried out using an Auto 306 Vacuum Coater (Edwards High Vacuum International) at an evaporation rate of ˜1 Å/s and a pressure of ˜4×10⁻⁶ mm Hg. Pt substrates were prepared by sputtering a ˜50 nm layer of chromium (CrC-100 sputtering systems from Plasma Sciences, Inc.), followed by a ˜120 nm layer of Pt on clean surfaces of single crystal Si wafer. Au substrates were cleaned immediately prior to use by placing them in an aqueous solution of H₂O₂/NH₄OH(H₂O₂:NH₄OH:H₂O=1:1:5) for 15 min, followed by a thorough washing with deionized water and ethanol. Pt substrates were used without further cleaning.

Self-assembly of thioacetates on Au was carried out in a vial which contained a piece of the Au substrate, the oligo(phenylene ethynylene) compound (1.0 mg), ethanol (20 mL), and NaOH (20 μL of a 0.27 M solution, final concentration 0.27 mM). The sample was removed and washed with acetone, THF and ethanol.

Electrochemical Assembly.

Solutions for the potential-driven electrochemical assembly were prepared as follows: To a vial was added ethanol (20 mL), an oligo(phenylene ethynylene) (1.0 mg), tetrabutylammonium tetrafluoroborate (0.33 g, 1 mmol), and 20 μL of aqueous 0.27 M NaOH. A CV-50W Voltammetric Analyzer (BAS, Bioanalytical Systems, Inc) was used to control the electrical potential applied to the electrodes. The auxiliary electrode was Pt wire and a nonaqueous Ag/AgNO₃ electrode was used as the reference. One of the following working electrodes was used: evaporated Au or Pt, an Au disk electrode, or a Pt disk electrode. The potential applied to the working electrode was +400 mV (vs Ag/AgNO₃ electrode). Assembled samples were washed with acetone, deionized water, and briefly sonicated in ethanol.

Measurements.

The thicknesses of the self-assembled monolayers were measured using an ellipsometer (Rudolph Instruments, Model: 431A31WL633). The He—Ne laser (632.8 nm) was incident at 70° to the sample surface. A refractive index (nf) of 1.55 was used for the film thickness calculation. Cyclic voltammograms were recorded by a CV-50W Voltammetric Analyzer (Bioanalytical Systems, Inc), employing a Pt counter electrode and a saturated calomel reference electrode (SCE). The working electrode was an Au electrode (MF-2014, Bioanalytical Systems, Inc.) or a Pt electrode (MF-2013, Bioanalytical Systems, Inc.) covered with a given oligo(phenylene ethynylene). The diameter of the Au and Pt electrodes was 1.6 mm. Cyclic voltammetry was performed in an aqueous solution of KCl/K₃[Fe(CN)₆] (0.1 M/1.0 mM) using a potential scan rate of 100 mV/s.

Infrared Spectroscopy.

The orientation and thickness of assembled monolayer were checked using IR analyses. Details about the procedure and instrumentation used for the external reflection and transmission IR measurements are known in the art.

There are three possible electrochemical methods for the deposition of molecular devices onto selected electrodes: 1) One can selectively deposit thiols on a biased Au electrode in the presence of an unbiased electrode. This method, to be useful, requires an appreciable different assembly rate between the biased and unbiased electrodes. 2) Conversely, one can permit assembly on an unbiased electrode while using a high potential to prevent assembly on the other electrode. 3) Lastly, one can uniformly form a SAM on both electrodes, then restore one electrode to its original bare state by the selective application of a high potential. For molecular electronic applications, the first approach is preferred. As described above, the present invention provided a technique for accomplishing the first method by allowing the molecules to assemble at a faster rate on the electrodes that are subjected to the potential than on the electrodes without potential.

Thiol Adsorption Kinetics on Au with and without Base or Electrostatic Potential

TABLE I
Thiol adsorption under open circuit conditions and with applied potential.

| | Film thickness [nm] | | | | |
|---|---|---|---|---|---|
| | Adsorption | | | | |
| Thiol Species | conditions* | 1 min | 10 min | 30 min | 24 h |
| 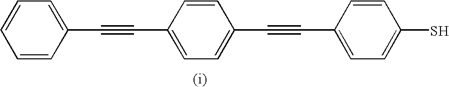 | Open ciecuit Open circuit +base +400 mV +400 mV +base | 1.8 1.8 2.7 | 2.0 | 2.4 | |
| 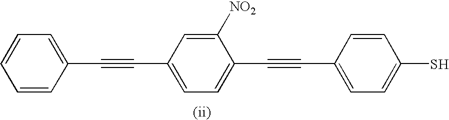 | Open circuit Open circuit +base +400 mV +400 mV +base | 1.5 2.1 | 1.7 2.5 | 2.4 | |
| 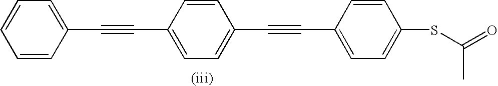 | Open circuit +400 mV | 0.3 0.2 | | 0.5 0.2 | |

^{a}The relative potentials were determined against a AgCl coated Ag wire in contact with the adsorption solution.

Alkanethiol adsorption isotherms typically show an initial rapid rise until the coverage reached 80-85% of a monolayer, followed by a second, slower step. Greater than 40% coverage was usually reached within the first 500 msec if the thiolate concentration was 1 mmol and within less than 60 sec. for a 1 μmol concentration. Overall, the aromatic thiol adsorption was found to be slower than the n-alkanethiol adsorption.

Approximately 0.1 mM solutions of the preferred thiol-terminated oligo(phenylene ethynylene)s in ethanol reach a half monolayer coverage in less than 1 minute. Their low solubility in ethanol probably compensates for the slower diffusion rate (Table 1). The addition of 1 μL 0.27 M NaOH per mL solution was found to have no significant influence on the adsorption rate.

A positive potential accelerates the thiol adsorption in the absence of a base and much more in combination with a base. The less soluble unsubstituted thiol shown at (i) in Table 1 forms a multilayer rapidly, and the more soluble nitro-substituted thiol (ii) reaches its theoretical monolayer thickness in 1 min instead of ˜1 h.

Thioacetates adsorb much more slowly than thiols. A solution with 1 mg of thioacetate 1(b) per 20 mL ethanol, or roughly 0.1 mM concentration, gives an 0.2 nm thick layer within 30 min, but the same was observed with a solution without thioacetate. Therefore, any layer formation can be attributed to advantageous adsorbate impurities, rather than to the thioacetate itself.

Assembly of Thioacetates with Base but without Potential

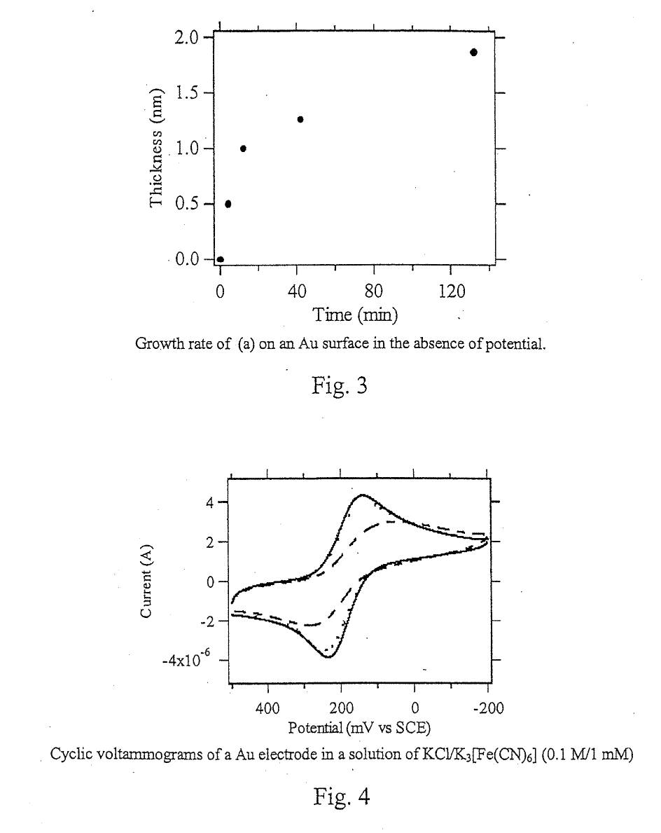

A 0.1 mM ethanolic solution of compound (a), which is shown in FIG. 1 and features two protected thiol termini, was assembled on Au after adding 1 μL 0.27 M NaOH per mL solution and the change in thickness over time was measured (FIG. 3). The adsorption was slower than for the free thiol despite the thioacetate groups on both ends.

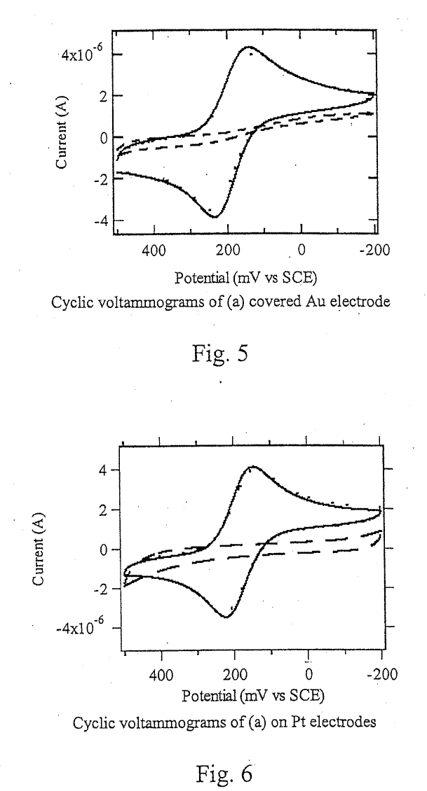

Cyclic voltammetry (CV), as an indication of the surface coverage ratio, corroborated the ellipsometry measurements. FIG. 4 shows the cyclic voltammogram of an Au electrode before and after immersion in a solution of (a). In FIG. 4, the solid line indicates the bare Au electrode; the dotted line corresponds to the Au electrode after immersion in 20 mL of 0.1 mM ethanolic solution of (a) with 20 μL aqueous solution of 0.27 M NaOH for 2 min. and the dashed line corresponds to the Au electrode after immersion in the same solution for 10 min. After immersion for 2 min., the peak current intensity dropped ˜10% and after immersion for 10 min., the peak current intensity dropped ˜55%, indicating that the surface coverage ratio of (a) on the Au electrode was ˜10% after 2 min and ˜55% after 10 min; in good agreement with the ellipsometry data.

Compounds containing electron-withdrawing groups and only one thioacetate end assembled even more slowly. Compound (b), for example, with a nitro group on the central phenyl ring, took 15 min to reach a film thickness of 0.4 nm.

The least polar methylmercapto-terminated biphenylthiols adsorbed 7 times faster than electron rich N,N-dimethylamino-terminated thiols and 20 times faster than electron poor nitro-terminated ones. Electron donor groups increase the gold sulfur binding energy but destabilize the monolayer because of their repulsive intermolecular dipole-dipole interactions. The slow adsorption of aromatic thiols with electron acceptor end groups is due to a weaker sulfur binding energy and stronger intermolecular electrostatic repulsion.

The majority of the deprotected thioacetate molecules in ethanol dissociate to thiolates with a high electron density on the sulfur, no matter what the substitutents are. The initial adsorption rates for a 0.1 mmol aromatic thioacetate/thiolate mixture without applied potential are however 1-2 orders of magnitude lower than for aromatic thiols: ˜2 min for 10% surface coverage versus less than 5 sec with aromatic thiols. The reaction between neutral ArS—H as a soft base and Au as a soft acid is fast, according to the hard-soft acid-base (HSAB) principle, while the thiolate adsorption on gold requires another molecule to become simultaneously reduced.

The relatively faster adsorption of dithiolates and thiolates with electron donor groups correlates again with a higher gold sulfur binding energy but also with their lower dissociation constant. Electron acceptor groups shift the equilibrium to the dissociated and slowly-adsorbing thiolate, while donor groups reduce the acidity of the thiol proton.

The positive potential on the gold adds an attractive force between the surface and the negatively charged thiolates without changing the thiol dissociation equilibrium. The attraction is strongest for the electron-rich thiolates where the negative charge is located at the sulfur atom. A positive potential therefore further increases the adsorption rate for the already preferred thiolates with electron donor groups. The foregoing observations are included for the purpose of illustration only and are not intended to define the chemical mechanisms involved in the present invention or to limit the scope of the claimed invention.

Assembly of Molecular Devices with an Applied Voltage

Table 2 summarizes the results of electrochemical assembly of a series of thioacetate derivatives on Au when a small amount of sodium hydroxide solution had been added. Under these conditions, the present compounds now quickly assemble under potential (compare FIG. 3 with entries 1-3 in Table 2) and the thickness of the layer increases with time (Table 2 entries 1-3, 14-16). Electron-donating groups, such as ethyl and methoxy groups, can aid in the formation of SAMs (entries 1, 17, 19). Electron-withdrawing groups, such as a nitro group (entries 8, 12) and a quinone unit (entry 14) tend to retard the growth rate. After 2 min, at +400 mV, most of the layers from electron-donating group-containing molecules reached their full length on the Au electrodes. (The molecular length of these compounds is ˜2.1 nm). Conversely, the compounds with strong electron-withdrawing groups were unable to assemble to their full length in 2 min. The right conditions for a complete monolayer coverage depend on the structure of the molecular device and have to be determined for each individual molecule. 2 min adsorption time on a Au surface at +400 mV positive potential are just right for the compounds 1(a) and 1(b), too short for 1(c) and 1(d), and too long for 1(e) and 1(f).

For mono-thioacetate molecular device components, the thickness of the assembled layers roughly correlates with the molecular length. One exception is compound (e), for which the layer is thicker than the length of the molecule (entries 17, 18). It is speculated that the excess adsorption in the case of the unfunctionalized phenylene-ethynylene-oligomers (e) and (h) is caused by their lower solubility in ethanol. A similar phenomenon has been observed in the self-assembly of long chain alkanethiols on Au from ethanol which gave a layer 20% thicker than the length of the molecule. Dithioacetates also formed multilayers upon extended assembly times, presumably due to disulfide formation as promoted by trace oxygen or the applied electric potential. To obtain a monolayer of dithioacetate molecular devices, a short assembly time in an atmosphere excluding oxygen should be employed.

We attempted to remove the layers assembled by the foregoing process, but once dried, the layer thicknesses remained virtually unchanged after sonication in THF, indicating that the excess molecules were either chemically bonded to the under layer or had been oxidized to the even less soluble disulfides.

TABLE 2
Thickness measurement for the potential-driven assembled film
on Au and Pt surface

| | Compound | | Potential | | | Thick- |
|---|---|---|---|---|---|---|
| Entry | (FIG. 1) | Surface | (mV vs Ag/AgNO₃) | Time | | ness |
| 1 | (a) | Au | +400 | 2 | min | 2.9 nm |
| 2 | (a) | Au | +400 | 6 | min | 3.2 nm |
| 3 | (a) | Au | +400 | 10 | min | 4.3 nm |
| 4 | (a) | Au | −800 | 10 | min | 1.0 nm |
| 5 | (a) | Au | −1000 | 10 | min | 0.5 nm |
| 6 | (a) | Pt | +400 | 2 | min | 2.0 nm |
| 7 | (a) | Pt | +400 | 10 | min | 3.6 nm |
| 8 | (b) | Au | +400 | 2 | min | 2.0 nm |
| 8b | (b) | Au | +0 | 15 | min | 0.4 nm |
| 9 | (b) | Au | +400 | 10 | min | 2.2 nm |
| 10 | (b) | Pt | +400 | 2 | min | 0.7 nm |
| 11 | (b) | Pt | +400 | 10 | min | 2.1 nm |
| 12* | (c) | Au | +400 | 2 | min | 0.4 nm |
| 13* | (c) | Au | +400 | 20 | min | 1.5 nm |
| 14 | (d) | Au | +400 | 2 | min | 0.3 nm |
| 15 | (d) | Au | +400 | 10 | min | 0.8 nm |
| 16 | (d) | Au | +400 | 20 | min | 1.8 nm |
| 17 | (e) | Au | +400 | 2 | min | 3.3 nm |
| 18 | (e) | Au | +400 | 10 | min | 3.9 nm |
| 19 | (f) | Au | +400 | 2 | min | 2.2 nm |
| 20 | (f) | Au | +400 | 10 | min | 6.1 nm |

*The base used here was concentrated ammonium hydroxide (20 μL).

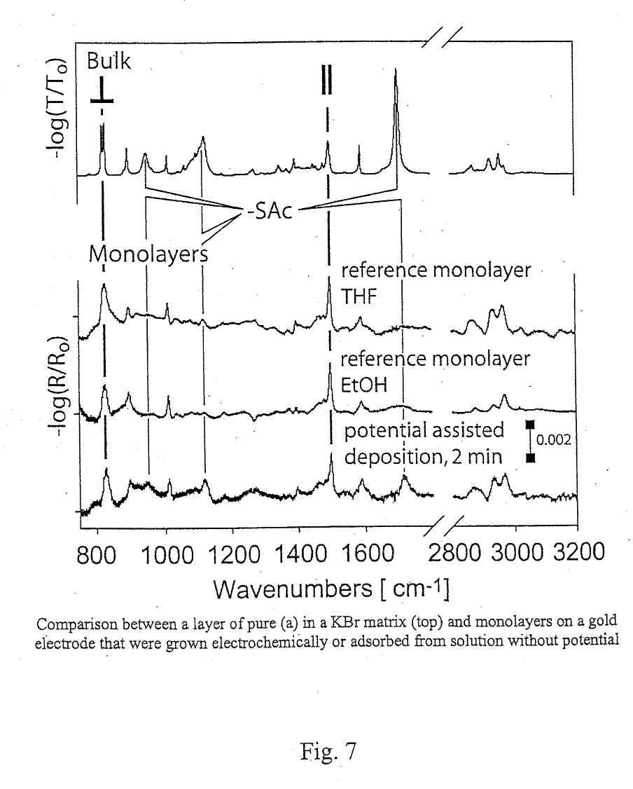

FIG. 5 shows the CV of an gold electrode covered with (a). It compares CV data from a bare gold electrode (solid line in FIG. 5), a covered gold electrode assembled without potential for 2 mm (dotted line in FIG. 5), and a covered gold electrode assembled with potential for 2 mm (dashed line in FIG. 5). In 2 min. nearly 100% of the gold surface was covered with a layer of (a). As shown in FIG. 5, assembly of the molecules with applied potential was significantly faster than without applied potential.

All of the CVs in FIG. 5 were recorded in an aqueous solution of KCl/K₃[Fe(CN)₆] (0.1 M/1 mM). The dotted line represents an electrode prepared without potential by immersing a bare platinum electrode for 2 mm in a 20 mL ethanolic solution containing (a) (1.0 mg, 2.1 μmol), Bu₄NBF₄ (0.33 g, 1 mmol), and aqueous solution of NaOH (20 μL, 5.4×10⁻³ mmol). The dashed line represents an electrode obtained by applying +400 mV (vs Ag/AgNO₃ electrode) on a bare gold electrode for 2 mm in a 20 mL ethanolic solution of (a) (0.1 mM), Bu₄NBF₄ (0.05 M), with aqueous solution of NaOH (20 μL, 5.4×10⁻³ mmol).

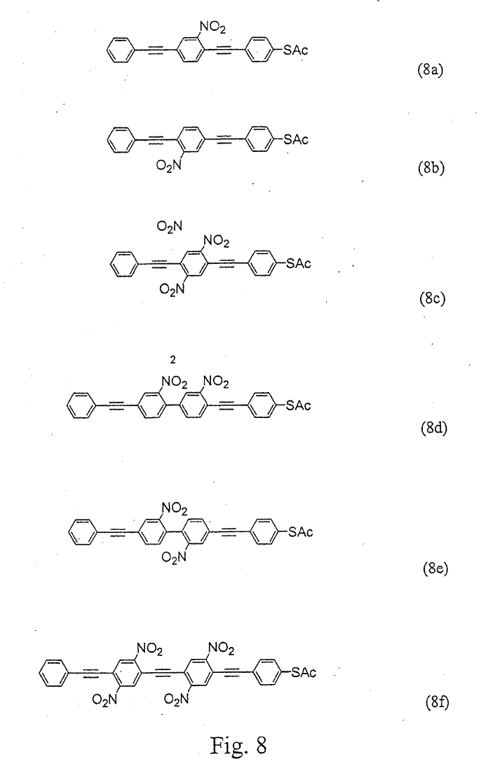

The present technique of assembly under electric potential works on platinum also. Table 2 above includes data for the potential-assisted assembly of compounds (a) and (b) on platinum (entries 6, 7, 10, 11). Layers of molecular device components grow more slowly on platinum than on gold. FIG. 6 shows cyclic voltammograms of a platinum electrode covered with (a) made by the potential assembly technique. In 10 min, the surface coverage ratio was nearly 100%. In contrast, the conventional chemical self-assembly of 1 on platinum, under the same conditions of base concentration, was very slow. After immersion of a platinum electrode in a solution of 1 in ethanol for 10 min, the surface coverage ratio was only ˜5% (FIG. 4).

All of the three cyclic voltammograms in FIG. 6 were recorded in an aqueous solution of KCl/K3[Fe(CN)6] (0.1 M/1 mM). The solid line represents the bare platinum electrode; the dotted line represents the platinum electrode prepared without potential by immersing for 10 min in an ethanol solution (20 mL) of (a) (1.0 mg, 2.1 μmol), Bu₄NBF₄ (0.33 g, 1 mmol), NaOH (20 μL, 5.4×10⁻³ mmol); and the dashed line represents the platinum electrode prepared by applying +400 mV (vs Ag/AgNO₃ electrode) on a bare platinum electrode for 10 min in the same solution.

From this point of view, platinum electrodes are better than gold electrodes because thiols grow more slowly on platinum than on gold via conventional chemical self-assembly. Under electric potential, the growth rates are nearly the same, although slightly slower on platinum. This greater disparity results in a wider operation time window for the controlled deposition of molecular device components. Put another way, the unbiased platinum electrode will be even cleaner than the unbiased gold electrode under the same conditions.

The foregoing paragraphs discuss the formation of a SAM of molecular device components on the surface of a gold or platinum substrate under positive electric potential. Conversely, as discussed above, a negative potential can prevent the formation of this layer. Table 2 lists the results of the application of (a) to a gold electrode under negative potential (entries 4, 5). When the applied potential is sufficiently negative, the growth of the molecular devices on the gold electrodes can be slowed significantly.

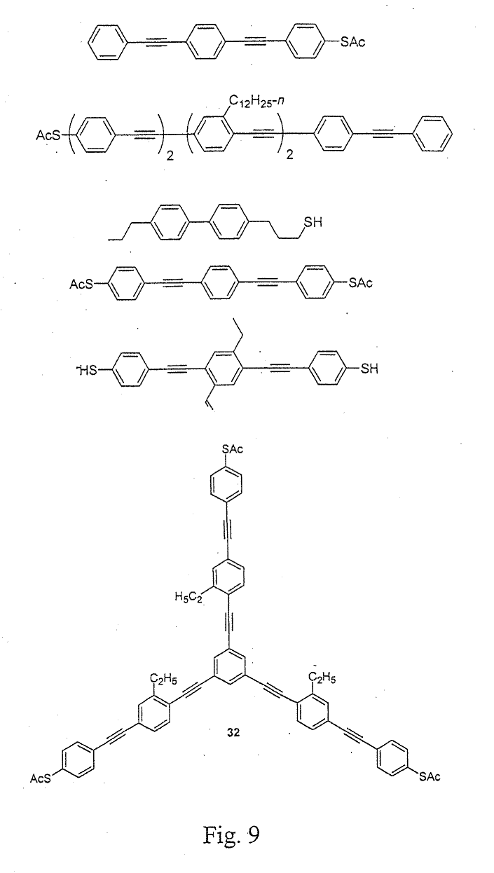

FIG. 7 shows the IR spectrum of polycrystalline (a) dithioacetate in a KBr matrix (top) and the spectra of three monolayers on gold. One of the monolayers was deposited under electric potential and the other two were deposited without applied potential. The monolayer from the adsorption with applied potential still has about half of its thioacetate groups uncleaved. We assume that the uncleaved ends are mostly at the film-air interface because no thioacetate bands were observed in the IR spectra of monolayers from partially cleaved monothioacetate solutions on gold.

The intrinsic band intensities can be determined from the transmission spectrum of a polycrystalline bulk sample, diluted with KBr and pressed into a transparent pellet. Differences between the intensities in the monolayer and bulk spectrum indicate an anisotropic film in which the molecules are aligned in a preferential direction. A semi-quantitative analysis is possible if the bulk and monolayer spectrum have at least two sufficiently intense bands with different orientations, i.e. parallel or perpendicular to the molecular main axis. Similar relative intensities for these two bands in the monolayer and bulk spectrum indicate that the molecules are either randomly oriented or that the molecules may be uniformly tilted by ˜54.7° (magic angle) from the surface normal.

Not all IR bands can be used for such a semi-quantitative analysis. Some of the bands are more sensitive to the changes in intermolecular distances and mobility. The best bands for a semi-quantitative analysis have the same position and width-at-half-height in the monolayer and polycrystalline bulk phase. The parallel mode at 1499 cm⁻¹ falls into this category. Among the perpendicular modes we can only take the doublet at 830/822 cm⁻¹ in the bulk spectrum that changes into a single band at 826 cm⁻¹ in the monolayer spectrum. The ratio of the integrated areas of these two bands are 0.61:1 and 0.62:1 for the chemically and potential-driven deposited monolayers respectively. This ratio also agrees with the result from the reference spectrum of the polycrystalline sample (0.58:1). The fast potential-driven deposition and the standard 24 h adsorption give monolayers with identical orientation. The molecules do not lie flat on the surface as they do at submonolayer coverages, but the higher coverage is not enough to reach an upright orientation.

In FIG. 7, transmission (T) and reflection (R) spectra are reported in absorbance units, defined as −log(T/T₀) and −log(R/R₀). The deposition under potential was done in 2 min in a solution of 20 mL ethanol with 2 μmol of 1 and 5 μmol of NaOH with a positive potential of 400 mV. The other two monolayers were prepared over 17 hours from THF with ammonium hydroxide as the base and from ethanol with NaOH as the base, respectively.

Self-Assembly of Thiolates on Gold Using Acid Deprotection.

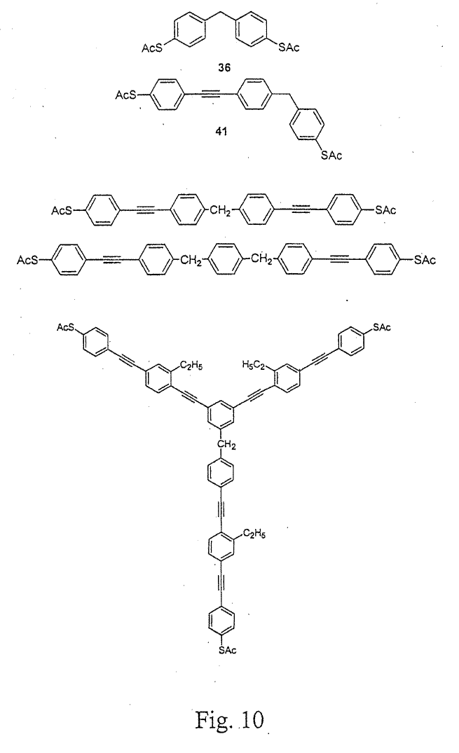

The concepts of the present invention have applicability to systems other than base-activated systems. Specifically, some molecular devices, including those shown in FIG. 8, can be selectively applied using acid deprotection, as described in detail below.

Gold Substrates

A single crystal silicon wafer was cut in 6×16 mm² sheets, then cleaned for 30 min in a hot (40° C.) fresh acidic peroxide (3:1 H₂SO₄/H₂O₂, v/v) solution, rinsed with a flowing distilled-water, ethanol and acetone, and the pieces of Si were dried in a flowing ultrahigh purity N₂ gas. The gold films were deposited by thermal evaporation of 200 nm thick Au onto the Si sheets with a 25 nm Cr adhesion layer at a rate of 1 Å/s under the vacuum of 2×10⁻⁶ Torr. The gold samples were finally stored in a N₂ atmosphere. Before use, the gold substrates were cleaned by a UV/O₃ cleaner (Boekel Industries, Inc., Model 135500) for 10 min in order to remove organic contamination, followed by ultrasonic cleaning in ethanol for 20 min to remove the resulting gold oxide layer, rinsing with ethanol and acetone, then dried in flowing N₂. This procedure was confirmed to provide a clean, reproducible gold surface.

Chemicals

Methylene chloride (CH₂Cl₂) and acetonitrile were distilled from calcium hydride. Tetrahydrofuran was distilled from sodium/benzophenone ketyl. All other chemicals were used as received without further purification. The syntheses of compounds such as those in FIG. 8 are well known. See, for example, Chem. Eur. J. 2001, 7, No. 23, 5118-5134, cited above.

Solution Preparation for Acid-Promoted Method

The compound (1 mg) was dissolved with a solvent mixture of CH₂Cl₂/MeOH (2:1, v/v) in a 4 mL vial. 50-70 μL of concentrated H₂SO₄ was then added and the solution was incubated for 1-4 h in order to give deprotection of thiol moiety.

Chemical Assembly

The cleaned gold substrates were immersed into the adsorbate solutions at room temperature for a period of 20-24 h. All the solutions were freshly prepared, previously purged with N₂ for an oxygen-free environment and kept in the dark during immersion to avoid photo-oxidation. After the assembly, the samples were removed from the solutions, rinsed thoroughly with acetone, MeOH and CH₂Cl₂, and finally blown dry with N₂.

Potential-Assisted Assembly

The same three-electrode cell described above was used with a gold substrate as the working electrode, a platinum wire as the counter electrode, and an Ag/AgNO₃ (10 mM AgNO₃ and 0.1 M Bu₄NBF₄ in acetonitrile) reference electrode. The monolayers were deposited by the constant potential of 400 mV for 5-60 min in the SAM solutions. After the modification, the samples were removed from the solutions, rinsed with acetone, MeOH and CH₂Cl₂, and blown dry with N₂.

Electrochemical Measurement

Cyclic voltammetry (CV) for SAM formation was performed in an aqueous solution with 1 mM K₃[Fe(CN)₆] and 0.1 M KCl between −0.2 and +0.6 V (vs. SCE) at the rate of 100 mV/s. An Au disk electrode (MF-2014, BAS) with diameter 1.6 mm was used as the working electrode, a saturated calomel electrode (SCE) as a reference electrode and a Pt wire as a counter electrode.

Ellipsometry

Monolayer thickness was determined using a Rudolph series 431A ellipsometry. The He—Ne laser (632.8 nm) light was incident at 70° on the sample. Measurements were carried out before and immediately after monolayer adsorption. All the thickness was calculated based on the refractive index of n_{f}=1.55. The length of the molecular wire was calculated from a sulfur atom to the furthest proton for the minimum energy extended forms by molecular mechanics. The theoretical thickness was then obtained with the assumed linear Au—S—C bond angles and 0.24 nm for the Au—S bond length.

UV-Vis Spectroscopy

The UV-Vis spectroscopes were recorded by UV-Vis-NIR scanning spectrophotometer (Shimadzu, UV-3101 PC).

As described above, the thiolacetyl groups of molecular device compounds are easily deprotected to the free thiol or thiolate by deacylation with NH₄OH, and then the SAM are formed on a gold surface by Au—S bonding. Table 3 illustrates the chemical assembly of molecular wires in a single solvent. The measured thickness of mononitro compounds (1 and 2) are near to the theoretical values. It indicates a compact monolayer has been formed. On the other hand, the thickness of multi-nitro compounds exhibit a large difference compared to the calculated values. A slower rate of adsorption is detected. The strong electron-withdrawing nitro group reduces the interaction of Au and S, finally results in the slower assembly rate and the poor adsorption on Au surface. Moreover, the multi-nitro groups of conjugated molecules are possibly attacked by hydroxide during the long assembly time, which decomposes the compounds and induces a precipitation in the unstable solution accompanied by color changes from yellow-green to brown.

TABLE 3
Chemical assembly of thiolacetyl-terminated
molecular wires in a single solvent.

| | | | | Experimental | Calculated |
|---|---|---|---|---|---|
| | | | Time | Thickness | Thickness |
| Compound | Solvent | Base | (h) | (nm)^{a} | (nm)^{b} |
| (8a) | EtOH | NH₄OH | 24 | 2.4 | 2.14 |
| (8b) | EtOH | NH₄OH | 24 | 2.0 | 2.14 |
| (8c) | THF | NH₄OH | 24 | 1.0 | 2.14 |
| (8d) | THF | NH₄OH | 24 | 0.8 | 2.62 |
| (8e) | THF | NH₄OH | 24 | 0.7 | 2.62 |
| (8f) | THF | NH₄OH | 24 | 1.6 | 2.86 |

^{a}The value measured by ellipsometry.
^{b}The theoretical thickness calculated by molecular mechanics without the consideration of the tilt angle of molecular wire in SAM.

Thus, to get a well-ordered SAM of multi-nitro molecular wires, a mixed solvent is preferred and is selected based on the solubility and deprotection system. As shown in Table 4, the acetone/methanol solvent mixture performs best in the base-promoted method. All the SAM of dinitro compounds ((8c), (8d), (8e)) display thickness the same as the theoretical value after reaction of 24 h, thus complete assembly is achieved. Conversely, the tetra-nitro compound (8f) is not well assembled in the base-promoted system, as indicated by the relatively large difference between measured and theoretical thickness.

TABLE 4
Chemical assembly of thiolacetyl-terminated
molecular wires in a mixed solvent.

| | | | | | | Calcu- |
|---|---|---|---|---|---|---|
| | | | | | Ex- | lated |
| | | | | | perimental | Thick- |
| Com- | | | | Time | Thickness | ness |
| pound | Solvent^{a} | Acid | Base | (h) | (nm) | (nm) |
| (8c) | Acetone/MeOH | — | NH₄OH | 24 | 2.0 | 2.14 |
| (8d) | Acetone/MeOH | — | NH₄OH | 24 | 2.5 | 2.62 |
| (8e) | Acetone/MeOH | — | NH₄OH | 24 | 2.4 | 2.62 |
| (8f) | Acetone/MeOH | — | NH₄OH | 24 | 2.0 | 2.86 |
| (8c) | Acetone/MeOH | — | Cs₂CO₃ | 24 | 2.4 | 2.14 |
| (8c) | CH₂Cl₂/MeOH | H₂SO₄ | — | 24 | 2.2 | 2.14 |
| (8d) | CH₂Cl₂/MeOH | H₂SO₄ | — | 24 | 2.4 | 2.62 |
| (8e) | CH₂Cl₂/MeOH | H₂SO₄ | — | 24 | 2.5 | 2.62 |
| (8f) | CH₂Cl₂/MeOH | H₂SO₄ | — | 24 | 2.9 | 2.86 |

^{a}The ratio of mixed solvent is 2:1.

An external electric field applied at the interface of liquid/gold can greatly change the assembly reaction rate and lead to a kinetically rather than thermodynamically controlled deposition process. UV-Vis spectra confirm that the acid-promoted method affords a more stable solution and it is reliable. Table 5 summarizes the results of potential-assisted assembly of various molecular wires on a gold electrode. The assembly rate is very fast and the SAM thickness increases with time. The rate of potential-assisted assembly is increased 10-100 times compared to the rate of the chemical assembly. In the base-promoted electrochemical assembly, the mononitro- and dinitro-compounds ((8a), (8c), (8e)) show a good assembly and near full-coverage on Au. The tetranitro compound (8f) slowly forms SAMs by base catalysis with either the potential-assisted procedure or the chemical method, as illustrated in Table 4. By using an acid-promoted electrochemical method, however, all the nitro-compounds ((8c), (8e), (8f)) can be completely assembled after a 60 min deposition time. The potential-assisted assembly is rapid and reproducible. UV-Vis spectra confirm that the acid-promoted method affords a more stable solution and it is reliable.

TABLE 5
Potential-assisted assembly of thiolacetyl-terminated
molecular wires on gold electrode.

| | | | | | | Reduced |
|---|---|---|---|---|---|---|
| | | | | | | ratio of |
| | | | | Po- | | redox |
| Com- | | | | tential | Time | peak |
| pound | Solvent^{a} | Acid | Base | (mV) | (min) | current^{b} |
| (8a) | EtOH | — | NH₄OH | 400 | 5 | 99% |
| (8c) | Acetone/MeOH | — | NH₄OH | 400 | 60 | 87% |
| (8e) | Acetone/MeOH | — | NH₄OH | 400 | 30 | 59% |
| (8e) | Acetone/MeOH | — | NH₄OH | 400 | 60 | 95% |
| (8f) | Acetone/MeOH | — | NH₄OH | 400 | 60 | 22% |
| Bare Au | | | | | | 0% |
| (8c) | CH₂Cl₂/MeOH | H₂SO₄ | — | 400 | 60 | 90% |
| (8e) | CH₂Cl₂/MeOH | H₂SO₄ | — | 400 | 60 | 97% |
| (8f) | CH₂Cl₂/MeOH | H₂SO₄ | — | 400 | 60 | 96% |

^{a}The ratio of mixed solvent is 2:1.
^{b}The reduced ratio of redox peak current is deduced by (1 − I_{SAM}/I_{Au})% from CVs in an aqueous solution of K₃[Fe(CN)₆]/KCl.

In the common chemical assembly, which is a passive incubation process, the open circuit potential (OCP) is about −200 to −300 mV. However, in an external positive electric field, the thiol and thiolate with negative charge can strongly adsorb on Au, therefore, a modest anodic potential (i.e., 400 mV) can greatly enhance the assembly rate. A lower negative potential will impede the assembly reaction and even peel away the existing SAM. Conversely, a higher positive potential will induce the MeOH and Au oxidation, which also deform the SAM. By the careful selection of potential and solution, different molecular wires can be deposited on different parts of one electric device for the construction of a more complex logic circuit.

The present invention includes the voltage-assisted assembly of molecular devices on a substrate, with and without the rate differentiation that is results from the use of a chemical inhibitor, such as an acetate group. Thus, it is within the contemplated scope of the invention to accelerate the rate of assembly of a layer of molecular devices on a substrate using a voltage potential.

Nanocell Devices

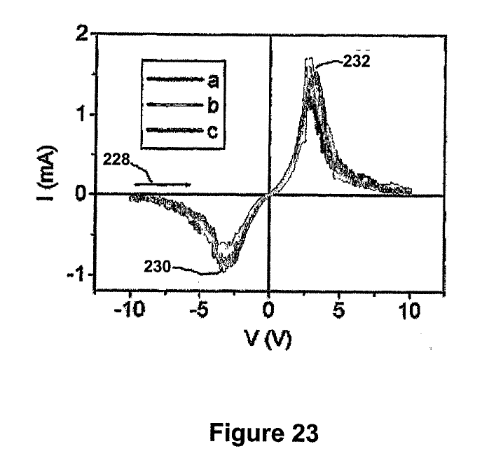

Turning to FIG. 21, there is shown a scanning electron microscope (SEM) image of a NanoCell 210 in accordance with the presently disclosed embodiment of the invention. As would be known to those of ordinary skill in the art, a NanoCell such as NanoCell 210 is, in the presently disclosed embodiment of the invention, a two-dimensional unit of juxtaposed electrodes fabricated atop a Si/SiO₂ platform or substrate 208. See, e.g., J. M. Tour et al., “Molecular Electronics: Commercial Insights, Chemistry, Devices, Architecture, and Programming,” World Scientific, New Jersey, (“Tour I”) which reference is hereby incorporated by reference herein in its entirety. See also, J. M. Tour et al., “NanoCell Electronic Memories,” Journal of the American Chemical Society, 2003, 125, pp. 13279-13283, which is also hereby incorporated by reference herein in its entirety. In the exemplary embodiment of FIG. 21, five spaced-apart pairs of juxtaposed micro-scale electrodes, 212-1 and 212-2, 214-1 and 214-2, 216-1 and 216-2, 218-1 and 218-2, and 220-1 and 220-2, respectively, are shown, though it is to be understood that a significantly greater number of electrodes, or fewer electrodes may be provided in a particular embodiment of the invention. Moreover, the choice of host platform material 208, Si/SiO₂ in the presently disclosed embodiment, is not critical. The host platform (substrate) may be comprised of other materials including, without limitation, glass, gallium arsenide (GaAs), or other suitable materials. However, the use of Si/SiO₂ or other oxide-coated semiconductor materials is believed to be preferable, inasmuch as this allows for the application of a biasing voltage to the substrate 208, producing what is referred to as a trans-conductance effect, as would be appreciated by those of ordinary skill in the art. Such a biasing voltage can be selected to affects the current between any two electrode pairs in the NanoCell 210 as desired in a particular application.

In the presently disclosed exemplary embodiment, the five gold (Au) electrode pairs 212-1 and 212-2 through 220-1 and 220-2 are patterned on opposing sides of the NanoCell 210. As shown in FIG. 21, the electrode pairs 212-1/212-2, 220-1/220-2 are disposed approximately 5 μm apart from one another, and a gap of approximately 5 μm separates each electrode in a given juxtaposed pair. It is contemplated that these spatial parameters may be altered in alternative embodiments. In particular, it is contemplated that each pair of electrodes may be spaced from approximately 0.001 to 100 μm from a neighboring pair. Furthermore, the gap between two juxtaposed electrodes in a pair can be either greater or less than that disclosed in the exemplary embodiment. Likewise, differing combinations of electrodes, such as 212-1 and 214-2, or 212-1 and 214-1, or any combination of two juxtaposed electrodes could also serve as electrode pairs to be addressed.

In one embodiment, a discontinuous gold film 222 is vapor-deposited onto the SiO₂ substrate in a central region of NanoCell 210, and each electrode among the aforementioned electrode pairs 212-1/212-2, 220-1/220-2 is in conductive contact with the discontinuous film 222. Conventional chemical vapor deposition (CVD) can be used for the purpose of creating the discontinuous film 222 in the desired region. Although gold is utilized for the formation of discontinuous film 222 in this particular embodiment of the invention, it is contemplated that other conductive materials such as palladium or platinum or carbon nanotubes or semiconductors such as graphite or silicon might be employed for such purpose, in embodiments which employ discontinuous conductive films. Likewise, while gold is similarly used in the formation of the electrode pairs, other conductive materials may be used for such purpose. Although the irregularity or randomness of discontinuous film 222 in the presently disclosed embodiment of the invention is believed to be inconsequential, it is also contemplated that an implementation of the present invention might employ a regular array of “dots” or “islands” of conductive material applied to substrate 208, and the term “discontinuous film” shall be construed for the purposes of the present disclosure shall be construed to encompass either of these alternatives. In the presently disclosed embodiment, discontinuous film 222 comprises a distributed array of “islands” of conductive material (gold, in the preferred embodiment). NanoCell 210 is preferably treated with UV-ozone and ethanol-washed immediately prior to use in order to remove exogenous organics. Electrical measurements experimentally confirm the absence of DC conduction paths across the discontinuous Au film 222 between the five juxtaposed pairs of ˜5 μm-spaced electrodes (≦1 picoamp up to 30 V). In the present embodiment, each juxtaposed electrode pair 212-1/212-2 . . . 220-1/220-2 serves as an independent memory bit address system. Moreover, as noted above, it has been shown that diagonally juxtaposed electrode pairs, for example, 212-1 and 214-2, 214-1 and 216-2, and, depending upon the electrode spacings, possibly such pairings as 212-1 and 216-2, and so on, can be programmed as separate memory bit address systems. It has been shown that such pairings can be independently and concurrently programmed without mutually disrupting others. Thus, for example, the electrode pair 212-1 and 212-2 can be programmed to a first value, while at the same time the electrode pair 212-1 and 214-2 can be independently programmed to another value without interfering with the 212-1/212-2 programming.

In accordance with one aspect of the invention, preparation of a NanoCell such as NanoCell 210 further involves deposition of a layer of interconnecting elongate nanowires 224 on top of discontinuous film 222. In this regard, several alternative embodiments are contemplated. In one embodiment, the nanowires 224 comprise gold nanorods (Au-nanorods) which are functionalized by being encapsulated with a molecular compound as will be hereinafter described in greater detail. In another embodiment, the nanowires 224 comprise carbon single-wall nanotubes (C-SWNTs) which are first partially encapsulated in gold and then encapsulated in a functional molecular compound. In still another embodiment, the nanowires 224 are nano-scale wires made of a refractory metal (palladium, platinum, or titanium, for example) characterized by their higher melting-points relative to gold. In yet another embodiment, the nanowires are nano-scale wires made of a semiconductor material, such as silicon (N-type or P-type), indium oxide (In₂0₃), or gallium arsenide (GaAs). A great many methods of synthesizing nanowires of various compositions are known in the art. See, as but one example, e.g., U.S. Pat. No. 6,313,015 to Lee et al., entitled “Growth Method for Silicon Nanowires and Nanoparticle Chains from Silicon Monoxide,” which patent is hereby incorporated by reference herein in its entirety. Likewise, the shape of the conductive or semiconductive nanoparticle is irrelevant. Nanowires 224 can take the form of a wire as disclosed herein, or alternatively may take the form of a spheroid, or be plate-like, for example. Accordingly, the term “nanowire” as used herein shall be construed broadly to encompass essentially any nanostructure having suitable dimensions to function as described herein in facilitating formation of programmable conductive pathways between juxtaposed electrodes in a NanoCell.

It is to be specifically noted further that in an alternative embodiment of the invention, the discontinuous conductive layer 222 may be omitted, such that the layer of interconnecting elongate nanowires 224 is deposited directly on substrate 208.

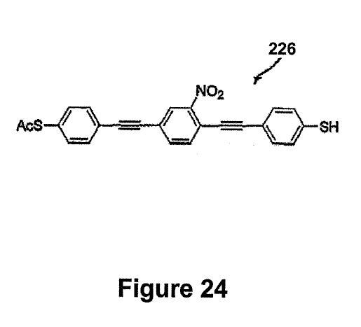

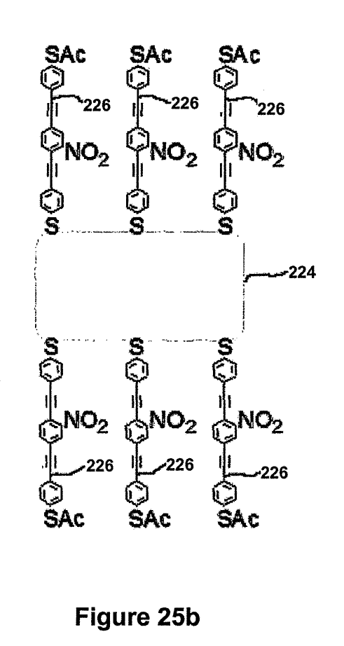

In FIG. 21, five juxtaposed pairs of fabricated leads across NanoCell 210 are shown, and some Au nanowires 224 are barely visible on the internal discontinuous Au film 222. FIG. 22 is a higher magnification of NanoCell 210, particularly the internal discontinuous Au film 222, showing the disordered discontinuous Au film 222 with an attached Au nanowire 224 which is affixed via an OPE-dithiol (not observable in FIG. 22) derived from a molecule 226 as chemically represented in FIG. 24. In the presently disclosed embodiment, molecule 226 was prepared by the formation of α-thiolacetate ω-thiol-tert-butoxycarbonyl. The latter is removed with trifluoroacetic acid (TFA) without disruption of the thiolacetate, using an orthogonal deprotection approach. See, e.g., Flatt, A. K.; Yao, Y.; Maya, F.; Tour, J. M. “Orthogonally Functionalized Oligomers for Controlled Self-Assembly,” J. Org. Chem., presently in press, which is hereby incorporated by reference herein in its entirety.)

The assembly of molecules 226 and nanowires 224 in the central portion 222 of NanoCell 210 is then carried out, preferably under N₂, to provide programmable current pathways across NanoCell 210. Compounds similar to the mononitro oligo(phenylene ethynylene) (OPE) molecule 226, shown in FIG. 24, have been shown previously to exhibit switching and memory storage effects when fixed between proximal Au probes. See, e.g., Chen et al., Science, 1999, v. 286, no. 1550; see also, Chen et al., Applied Phys. Letters, 2000, vol. 77, no. 1224. Molecule 226 shown in FIG. 24 is considered suitable for the purposes of the present invention; however, those of ordinary skill in the art will appreciate that there is a broad class of molecules which will exhibit the switching properties described herein, and it is to be understood that the present invention is by no means limited to use of the specific molecule 226 depicted in FIG. 24, which is shown for exemplary purposes only. See, e.g., Tour I, which details numerous molecular formulations having characteristics suitable for the purposes of the present invention.

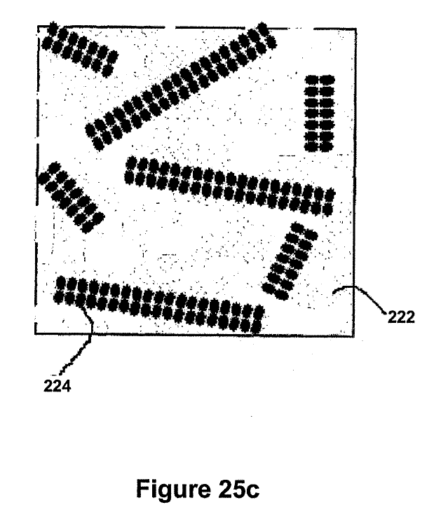

All nanowires 224 in the exemplary embodiment are substantially elongate nanostructures on the order of 1-50 (e.g., 30) nm in diameter and between 30 and 2000 nm in length. As noted above, however, it is contemplated that “nanowires” of greater or lesser diameters and lengths, and of various other shapes and forms, including spheres, disks, plates, etc may be suitable for the practice of the invention. In the disclosed embodiment, nanowires 224 are grown in a polycarbonate membrane by electrochemical reduction at 1.2 Coulombs) and are derivatized by being added to a vial containing molecules 226 (0.8 mg) in CH₂Cl₂ (3 mL). The vial is agitated (on a platform auto shaker, at 250 rμm) for 40 minutes to dissolve the polycarbonate membrane and to form Au nanowires encapsulated in OPE molecules 226 via chemisorption of the thiols to the nanowires. This is shown in FIG. 25a, which depicts a portion of the length of an Au nanowire 224 encapsulated in OPE molecules 226. Such assemblies of thiols on Au nanorods are known in the art; see, e.g., Martin et al., Adv. Mater., 1999, vol. 11, pp. 1021-1025; see also, Martin et al., Advanced Funct. Mater. 2002, vol. 12, p. 759. Because the thiol groups (SH) are far more reactive toward Au than thioacetyl groups, this procedure leaves the latter projecting away from the nanowire surfaces. This has been further verified by the assembly of molecules 226 on a surface of freshly deposited Au on Cr/Si for 24 hours in the absence and presence of polycarbonate, and checking by ellipsometry after well-rinsing the surface. Ellipsometric thicknesses are consistent with near-monolayer formation of molecules 26: 2.8±0.25 nm in the absence of polycarbonate (calculated 2.5 nm excluding the title tilt from the surface normal) and 3.1±0.25 nm in the presence of polycarbonate. Therefore, as expected, polycarbonate did not affect the SAM formation; however, a small amount of multilayer formation may occur presumably due to loss of the acetate and disulfide formation over the prolonged assembly time.

In the disclosed embodiment, NH₄OH (5 μL, conc.) and ethanol (0.5 mL) are added and the vial is agitated for 10 minutes to remove the acetyl group (Ac) and reveal the free thiol group, as shown in FIG. 25b. In an experimental embodiment, a device containing ten NanoCell structures 210 was placed in a vial (active side up), and the vial was further agitated for 27 hours to permit OPE-encapsulated nanowires 224 to interlink the discontinuous Au film 222 via the OPE-encapsulated nanowires 224. The chip is then removed, rinsed with acetone and gently blown dry with N₂. This results in a dispersion of nanowires 224 on top of discontinuous film 222 as shown in FIG. 25c.

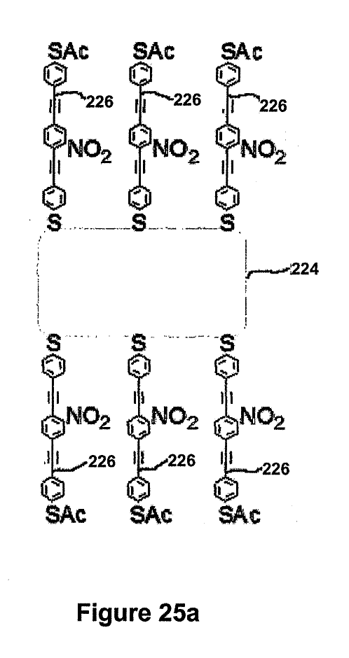

FIG. 23 plots the current-voltage (I(V)) characteristics (profile) of NanoCell 210 at 297 K (i.e., effectively room temperature). As will be familiar to those of ordinary skill in the art, an I(V) profile represents generally the relationship between the current flowing through an electronic device as a function of the voltages present at its input and output (and perhaps other) terminals. For example, a conventional CMOS (complementary metal-oxide semiconductor) transistor has source, drain, and gate terminals, and is characterized by the I(V) profile corresponding to its conductivity as various voltages are applied to and/or present at its source, drain, and gate terminals. The curves for the plots designated a, b and c in FIG. 23 are the first, second and third sweeps, respectively (40 sec/scan). The peak-to-valley ratios (PVRs) in plot c in FIG. 23 are 23:1 and 32:1 for the negative and positive switching peaks, respectively. Most significantly, the PVRs for NanoCell 210 are readily discernable on a macroscopic basis, hence rendering NanoCell device 210 of practical use as a computational element. (The black arrow designated with reference numeral 228 indicates the sweep direction of negative to positive.)

In the disclosed embodiment, the assembled NanoCell 210 is electrically tested on a probe station (Desert Cryogenics, TTProber 4) with a semiconductor parameter analyzer (Agilent 4155C) at room temperature (297 K) under vacuum (10⁻⁵ mm Hg). FIG. 23 presents a plot of the I(V) characteristics of NanoCell 210. Two stable and reproducible switching peaks 230 and 232 are observed in a bias range of −10 to +10 V. The I(V) profile is expectedly asymmetric because molecule 226, due to the nitro-group orientation, is asymmetrically oriented, and/or the contact pairs 212-1/212-2 . . . 220-1/220-2 are likely slightly different on each end. After about 300 scans, the switching responses further stabilizes in peak voltage; the device shows no degradation to greater than 2,000 scans over a 22 hour period of continuous sweeping. Also, after testing, assembled NanoCell 210 can be stored in a capped vial (air) for 2 months with little, if any, signal variations relative to the readings recorded at the initial testing.

In accordance with one aspect of the invention, a juxtaposed pair of electrodes, as described above, will show little variation in its behavior over several thousand scans. However, there may be notable differences when comparing different electrode pairs, in that they may show variations in peak current position (occurring for example between a range of 3-15 V), peak current (on the order of 0.1-1.7 mA), and PVR (on the order of 5-30). Those of ordinary skill in the art will recognize such differences to be related to the variations in the conduction pathways of these disordered arrays.

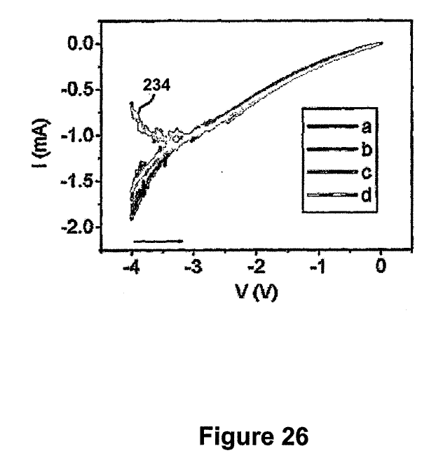

If a voltage sweep is conducted on NanoCell 210 in a bias range that is up to or not far beyond the peaks 230 and 232 of the I(V) curve (switching event), a substantially linear trace is observed, as shown by curve a (0-state) in FIG. 26. On the other hand, and in accordance with a significant aspect of the invention, it is apparent that NanoCell 210 is susceptible to programming to alternative states of operation/conductivity characterized by different I(V) profiles. In the presently disclosed embodiment, if three voltage pulses at −8 V (100 ms width, 104 ms period) are applied across a pair of leads (for example, leads 212-1 and 212-2), a peak 234 appears (1-state) in the first scan after the programming voltage pulses, as shown by curve b in FIG. 26. In accordance with one aspect of the invention, the programming voltage pulses set the system into new state that is then read by the bias sweep represented by the substantially non-linear I(V) profile represented by waveform b in FIG. 26. This is referred to herein as a switch-type memory effect. The following scans c and d in FIG. 26, however, exhibit substantially linear I(V) responses similar to waveform a, substantially similar to the scan before the voltage pulses, suggesting that the state set by the voltage pulse was erased after reading it by scan b. In other words, the switch type memory effect has a destructive-read property, which those of ordinary skill in the art will recognize as being comparable to a present-day dynamic random-access memory (DRAM). A positive voltage pulse, for example, +8 V, can also set the system into the 1-state. Voltages higher than ±8 V have proven to be effective, but voltages lower than ±8 V did not prove to reset NanoCell 210 in the exemplary embodiment into the 1-state. The inventors have observed all active NanoCells to exhibit this re-writable behavior, although the magnitudes and set voltages between different NanoCells may vary, as described above.

Summarizing, FIG. 26 shows the I(V) characteristics of NanoCell 210 before (waveform a) and after (waveforms b-d) three programming voltage pulses at −8 V at 297 K. Curves b, c, and d were the first, second, and third scan (after the −8 V reset pulses), respectively. Scans a-d were run at ˜40 s/scan. The results depicted in FIG. 26 are from the same NanoCell device 210 used to generate the I(V) curve in FIG. 23.

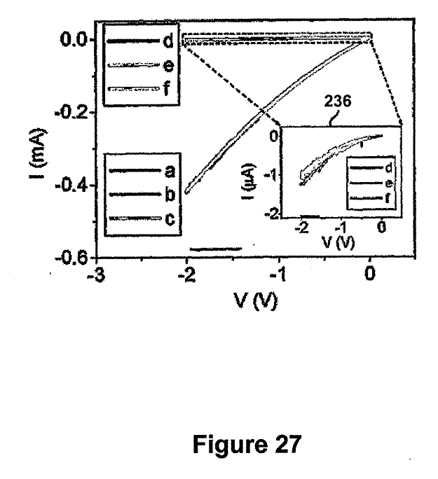

On the same device whose I(V) characteristics are shown in FIGS. 23 and 26, another type of memory effect has been shown to have a non-destructive-read, referred to herein as a conductivity-type memory, which operates by “programming” device 210 into either a high or low conductivity (σ) state. The difference between the switch-type memory and the conductivity-type memory is based upon the voltage-sweep range, namely, in the disclosed embodiment, −4 V to 0 V for the former and −2 V to 0 V for the latter. An initially high conductivity state (high σ or 0-state) can observed in a bias range of −2 to 0 V, as shown in FIG. 27, curves a-c. The high a state is changed (written, or programmed) into a low σ state (1-state) upon application of a number (three, in the presently preferred embodiment) voltage pulses at −8 V (100 ms width, 104 ms period), as shown by curves d-f in FIG. 27. Notably, the low σ state persists as a stored bit value (zero or one), and is essentially unaffected by successive read sweeps. There is a 400:10-state to 1-state ratio in current levels between the high and low σ states recorded at −2 V for NanoCell device 210. The ratios may vary between different electrode pairs but the ratio here is representative. 0:1 ratios of 12,500:1 (198 μA: 16 nA at −2.0 V) have been observed for a 5-μm gap electrode pair, ratios of 10:1 at the same voltage are the lowest observed.

To summarize, FIG. 27 shows the I(V) characteristics of NanoCell 210 before (scans a-c) and after (scans d-f) three voltage set-pulses, or programming pulses, of −8 V at 297 K (room temperature). The initial high σ state (0-state) is represented by curves a, b, and c, which are the first, second, and third scans before the set-pulse, respectively. The low C state (1-state) is represented by curves d, e, and f, which are the first, second, and third scans after the −8 V set-pulses, respectively. Inset 236 in FIG. 27 shows scans d-f in the μ-amp range. Scans a-c were run at ˜40 s/scan. Scans d-f were run at ˜50 sec/scan. This is the same device 210 whose I(V) characteristics are depicted in FIGS. 23 and 26.

The conductivity-type memory effect described herein is independent of bias sweep directions. Once set into the low σ state upon application of voltage-set (write/programming) pulses, NanoCell 210 holds the low σ state regardless of negative bias sweep from 0 to −2 V or positive bias sweep from 0 to 2 V. Several methodologies are contemplated for erasing the stored low σ state (written bit) in NanoCell 210. Voltage pulses at −3 V to −4 V (˜20 pulses at 1 ms pulse width, 10 ms pulse period) have been shown to reset the memory into the original high σ state (using a voltage pulse that comes near the peak of the switching event but not far past the peak). Although the overall write, read, erase sequence used in the screening of these devices might be regarded as slow due to the resetting time of the probing electronics, the inherent switching may be on the order of milliseconds, or faster, for each operation if customized electronics are used. The switch-type and conductivity-type memory effects are disclosed herein in the negative bias regions; however, they apply in positive bias region as well.

The bit retention time for the switch-type memory has been experimentally proven to be lengthy, and in experimental settings at least 11 days with ˜10% change in the voltage peak position of the curves when compared to the read-tests run seconds after setting the written state; however, there seems to be no decline in the magnitude of the response, suggesting that the persistence could be significantly longer than the experimentally observed results. The conductivity-type memory has been experimentally shown to persist for at least 9 days. Over this period, the 0:1 signal magnitudes actually have been shown to increase, although the reset voltages may also drift higher (˜10%) over such a period. Therefore, the two types of memory effects can have much longer retention times, but these are merely the time periods over which they have been tested. During waiting periods over which these retention times were recorded, the NanoCells had been occasionally exposed to air (1 atm), for periods of up to 30 min, as more samples were moved through the testing chamber. Therefore, the stored written states are robust even with short exposure to air.

Yields of functioning NanoCells 210 that have been prepared by the protocol described herein appear to be electrode gap-dependent. A thus-prepared NanoCell has experimentally exhibited 100%, 65%, and 30% yields for devices with 5 (as in NanoCell 210), 10, and 20 μm-spacings between the juxtaposed electrodes, respectively.

In experimental trials, assembled NanoCells like NanoCell 210 were tested in a probe station both in the dark (covering the observation window with aluminum foil) and in the presence of the room light with the station's fiber optic observation light projected through the observation window ˜10 cm above the chip. The same electrical responses were obtained regardless of the lighting, thereby apparently excluding a photoconductive mechanism.

While not implying to be bound by the precise mechanism for the NanoCell behavior, several control experiments have been conducted in order to investigate the mechanism of action for the NanoCell memories like NanoCell 210. When the same assembly process was conducted but molecule 226 was not added (only Au nanowires in polycarbonate, CH₂Cl₂, NH₄OH and ethanol were added), all the leads were “open” and no switching behavior was observed over tested juxtaposed electrodes (pairs at 5 μm-spacings, 10 μm-spacings and 20 μm-spacings). Therefore, the process appears to be dependent upon introduction of molecule 226. When the assembly procedure is conducted but the nanowires were not present (adding only molecule 226, polycarbonate devoid of nanowires, CH₂Cl₂, NH₄OH and ethanol), two out of three juxtaposed 5 μm-spaced electrodes showed switching between them; however, the switching effect signal degraded nearly completely after 3-10 scans. Therefore some molecules may have bridged the discontinuous Au film, but the connections were not as abundant or stable. A similar behavior was observed at 10 μm-spacings between the electrodes. When an alkyl system, AcS(CH₂)₁₂SH was substituted for molecule 226 in the standard assembly process, and thirty juxtaposed electrode pairs were studied, twenty-eight showed no device behavior. Interestingly, however, one 5 μm-spaced electrode pair showed the characteristic switching that dissipated after three scans while a second electrode pair showed reproducible switching behavior but the onset and peak currents occurred at 14 V. Therefore, it appears that molecule 226 is not unique among molecule types.

Concerning the mechanism underlying the programmability of NanoCells such as NanoCell 210, a molecular electronic effect has been considered. Several mechanisms have been proposed for molecular electronic switching. See, e.g., Seminario et al., Journal of the American Chemical Society, vol. 124, pp. 10266-10267 (2002); see also, Cornil et al., Journal of the American Chemical Society, vol. 124, pp. 3516-3517 (2002). These mechanisms are based upon charging of the molecules which results in changes in the contiguous structure of the lowest unoccupied molecular orbital (LUMO). This can further be accompanied by conformational changes that would modulate the current based on changes in the extended π-overlap. As the voltage is increased, the molecules in discrete nano-domains would enter into differing electronic states. Conversely, as some have pointed out, so called “molecular-based” switching might not be an inherently molecular phenomenon, but rather results from surface bonding rearrangements that are molecule/metal contact in origin (i.e. a sulfur atom changing its hybridization state, or more simply, sub-angstrom shifts between different Au surface atom bonding modes, or molecular tilting). An estimate of the number of molecular junctions between a set of juxtaposed electrode pairs is difficult to gauge; however, based upon the size of the nanowires and the Au islands (which can be 0.3-1 μm long), the number of molecular junctions could be as few as four in a 5 μm-electrode gap. The number of molecules in parallel, per junction, could be as few as 1 or as many as several thousand, based on the nanowire diameters, lengths and shapes. Note that the quantum conductance of each molecule is ˜0.08 mA/v.

In addition to a molecular electronic process, electrode migration has been considered as a cause for the high currents and reset operations that are analogous to filamentary metal memories. To further investigate this point, the exposed organic material has been stripped from a working NanoCell 210 by treating the assembled chip with UV-ozone for 10-30 minutes. Notably, the device behavior of NanoCell 210 remained and often improved. In some cases, the 0:1 bit level ratios for the conductivity memory even increased up to 10⁶:1 (2.53 mA: 0.76 nA at −3.0 V). This could suggest that the ozone was not able to penetrate through the build-up of the oxidatively destroyed organics in order to reach the small amount of active organic molecules in the key nano-domains that are sandwiched between the nanowires and the Au islands in discontinuous Au layer 222, and that the more exposed leakage routes were destroyed by the ozone. Conversely, it could suggest that indeed filamentary metal had grown along the molecules and that these metal filaments were causing the observed switching behavior, with any molecular leakage routes being destroyed by the ozone. It has been previously shown, by modeling, that the NanoCell 210 should exhibit extraordinary resistance to degradation (defect tolerance) due to the abundance of molecules available for switching; furthermore, if one molecule degrades, another could slip into place from the self-assembled monolayers that cover all the surrounding metal surfaces. It will also be apparent to those of ordinary skill that at the atomistic level, a molecular change in either conformation or hybridization at the metal-molecule interface, due to voltage changes or charging, could give electronic response characteristics that are analogous to filamentary metals (atoms moving in and out of alignment for current flow), and thereby resemble negative differential resistance-like behavior. In other words, metallic nanofilaments forming during a voltage sweep, then on increasing the voltage, they could exhibit a sudden break, causing a decline in the current.

Additionally, a mechanical motion involving the molecule-encapsulated nanowires has been considered. However, it was deemed less likely due to the highly crosslinked nature of the micron-sized matrix.

None of the data presented herein is regarded by the inventors as conclusive enough to exclude either the molecular electronic-based mechanism or the nanofilament mechanism. However, findings point toward the nanofilament-based mechanism being the dominant or exclusive pathway. This assessment is not to be construed as limiting as to the scope of the claims of the present disclosure.

On the other hand, in NanoCells which are allowed to age for significant periods of time, on the order of four months, switching with magnitudes on the order discussed herein have been observed, even where neither nanowires 224 nor molecules 226 were added. One possible explanation for this phenomenon is that the islands in discontinuous Au layer 222 migrated sufficiently close together to form nanofilaments upon voltage scanning, and then metal filament breakage occurred at higher voltages, giving responses similar to those depicted in FIG. 23.

I(V,T) (current as a function of voltage and temperature) measurements have been made to assess the possible conduction mechanism of the high-σ conductivity-type memory state on a bare NanoCell. The data suggests “dirty” or modified-metal conduction, i.e., metallic conduction with trace impurities. The same type of I(V,T) measurements on a molecule/nanowire assembled NanoCell showed both a temperature dependence and a non-temperature dependence based on the particular juxtaposed electrode set studied. It is believed by the inventors that there may be a duality of conduction mechanisms co-existing in a given NanoCell 210.

From the foregoing description of one or more particular implementations and embodiments of the invention, it should be apparent that a NanoCell 210 assembled with disordered arrays of nano-wires has been disclosed. The NanoCell 210 exhibits reproducible switching behavior and at least two types of memory effects, one of which being a destructive-read and the second a nondestructive-read. Both types of memory functionalities are stable for a persistent period of time at room temperature and probably much longer. Data suggests that nanofilamentary metal formation may be the mode of current transport, but fabrication of NanoCells with more refractory metals such as Pt or Pd are also feasible. Additionally, it may be feasible to make NanoCells with a differently-configured stepper or even more precise fabrication tools and techniques to yield juxtaposed electrode gap spacings of less than 1 μm with smaller Au-film islands and appropriately sized and shaped nanowires, to attain higher degrees of consistency between electrode pairs. The present invention is believed to represent the first embodiment of a disordered nano-scale ensemble for high-yielding switching and memory while mitigating the painstaking task of nano-scale lithography or patterning; thereby furthering the promise of disordered programmable arrays for complex device functionality.

Although a broad range of implementation details have been disclosed and discussed herein, these are not to be taken as limitations as to the range and scope of the present invention as defined by the appended claims. A broad range of implementation-specific variations, alterations, and substitutions from the disclosed embodiments, whether or not specifically mentioned herein, may be practiced without departing from the spirit and scope of the invention as defined in the appended claims. By way of example but not limitation, those of ordinary skill in the art having the benefit of the present disclosure will recognize that “nanowires” 224 may take on a variety of different forms and sizes while still functioning as intended in facilitating the formation of programmable conductive paths between juxtaposed electrodes. Likewise, nanowires 224 may be made of a variety of different materials, not limited to those alternatives which are specifically identified in this disclosure. Furthermore, in embodiments of the invention incorporating a discontinuous conductive film 222, it is to be understood that such a film may be composed of conductive materials other than gold, and may be random and irregular, as disclosed herein, or may comprise an ordered grid of nano-particle sized “dots” or “islands” of conductive material.

While preferred embodiments of the present invention have been discussed in detail herein, it will be understood that various modifications could be made thereto without departing from the scope of the invention. For example, the molecular devices, protective groups, solvents, electrolytes, electrodes, substrates, substrate surfaces, deprotection mechanisms, and activation mechanisms can all be varied. In addition, order in which the various steps of the present methods are performed can be varied. Unless order is explicitly recited in the claims, the mere recitation of claim steps in an order is not intended to require that the steps be performed in that order, or that one step must be completed before the next step can begin.

What is claimed is:

1. A method for selectively assembling a molecular device comprising:
(a) providing a base with a first substrate and a second substrate;
(b) contacting the first substrate with a solution containing molecular device molecules;
(c) impeding bonding of the molecular device molecules to the second substrate sufficiently that application of a voltage potential to the first substrate results in assembly of the molecular device molecules on the first substrate at a rate that is at least 1.5 times the rate of assembly of the molecular device molecules on the second substrate; and
(d) applying a voltage potential to the first substrate so as to cause the molecular device molecules to assemble on the first substrate.

2. The method according to claim 1 wherein application of a voltage potential to the first substrate results in assembly of the molecular device on the first substrate at a rate that is at least 2 times the rate of assembly of the molecular device on the second substrate.

3. The method according to claim 1 wherein application of a voltage potential to the first substrate results in assembly of the molecular device molecules on the first substrate at a rate that is at least 10 times the rate of assembly of the molecular device on the second substrate.

4. The method according to claim 1 wherein application of a voltage potential to the first substrate results in assembly of the molecular device molecules on the first substrate at a rate that is at least 100 times the rate of assembly of the molecular device molecules on the second substrate.

5. The method according to claim 1, further comprising:
(a) contacting the first and second substrates with a solution containing second-type molecular device molecules that are different from the molecular device molecules of step (b) such that said second-type molecular device molecules assemble on said second substrate.

6. The method according to claim 5, further comprising electrically connecting the molecular device molecules assembled on the first substrate with the second-type molecular device molecules assembled on the second substrate with a conducting material.

7. The method according to claim 1, wherein the bonding of the molecular device to the substrate is impeded by providing a protecting group on the molecular device molecule.

8. The method according to claim 1, wherein the molecular device molecules comprise oligo(phenylene ethynylenes).

9. The method according to claim 1, wherein the molecular device molecules comprise thiol-terminated oligo(phenylene ethynylenes) in a solution that includes a base.

10. A method for assembling a molecular circuit on a first substrate, comprising:
(a) providing a solution comprising molecular device molecules, each molecular device molecule having a metal-bonding terminus protected by a protecting group;
(b) contacting the first substrate with said solution; and
(c) applying a voltage to the first substrate resulting in assisted removal of said protecting group allowing the metal-bonding termini to bond to the first substrate such that the molecular device molecules assemble on the first substrate.

11. The method according to claim 10, wherein said solution further comprises a base.

12. The method according to claim 10, wherein said solution further comprises an acid.

13. The method according to claim 10, wherein the molecular device molecule comprises oligo(phenylene ethynylenes).

14. The method according to claim 10, wherein the protecting group is selected from the group consisting of: thioethers, S-diphenylmethyl thioethers, substituted S-diphenylmethyl thioethers, and S-triphenylmethyl thioethers, substituted S-methyl derivatives, substituted S-ethyl derivatives, silyl thioethers, thioesters, thiocarbonate derivatives, thiocarbamate derivatives, and thioacetates/thiolacetates/thioacetyls.

15. The method according to claim 10, wherein the protecting group comprises acetate.

16. The method according to claim 10, further including repeating steps (a)-(c) with a second substrate and with a second-type of molecular device molecule that is different from the molecular device molecules assembled on the first substrate.

17. A method for assembling a molecular circuit on a metal substrate, comprising:
(a) providing a mixture comprising molecular device molecules in solution, each molecular device molecule having a metal-bonding group;
(b) contacting the metal substrate with the solution; and
(c) applying a voltage potential to the substrate so as to attract the metal-bonding groups to bond to the substrate such that the molecular devices assemble on the substrate.

18. A molecular circuit prepared by:
(a) contacting a first substrate with a solution containing molecular device molecules;
(b) impeding bonding of the molecular device molecules to the substrate sufficiently that application of a voltage potential to the substrate results in assembly of the molecular device on the substrate at a rate that is at least 1.5 times the rate of assembly of the molecular device on a voltage-neutral substrate; and
(c) applying a voltage potential to the first substrate so as to cause the molecular device molecules to assemble on the first substrate.

19. The molecular circuit of claim 18, further prepared by:
(a) providing a second substrate adjacent to the first substrate;
(b) contacting the first and second substrates with a solution containing second-type molecular device molecules that are different from the molecular device molecules of step (a) such that said second-type molecular device molecules assemble on said second substrate; and
(c) electrically connecting the molecular device molecules assembled on the first substrate to the second-type molecular device molecules assembled on the second substrate with a conducting material.

20. A nanoscale computing device, comprising:
a substrate;
a pair of conductive input/output electrodes carried on said substrate and disposed in spaced-apart relationship;
a substantially disordered assembly of nanowires formed on said substrate in a region between said electrodes, thereby forming at least one programmable conductive pathway between said pair of electrodes.

21. A nanoscale computing device in accordance with claim 20, wherein said nanowires are molecularly encapsulated.

22. A nanoscale computing device in accordance with claim 21, wherein said nanowires comprise gold nanorods.

23. A nanoscale computing device in accordance with claim 21, wherein said nanowires comprise single-wall carbon nanotubes.

24. A nanoscale computing device in accordance with claim 23, wherein said single-wall carbon nanotubes are at least partially encapsulated in gold prior to being molecularly encapsulated.

25. A nanoscale computing device in accordance with claim 21, wherein said nanowires comprise refractory metal wires.

26. A nanoscale computing device in accordance with claim 21, wherein said nanowires comprise semiconductive material.

27. A nanoscale computing device in accordance with claim 21, wherein said nanowires are substantially elongate.

28. A nanoscale computing device in accordance with claim 27, wherein said nanowires are approximately 1-50 nm in diameter and approximately 30-2000 nm long.

29. A nanoscale computing device in accordance with claim 20, wherein said substrate is formed of a semiconductive material.

30. A nanoscale computing device in accordance with claim 29, wherein said semiconductive material is Si/SiO₂.

31. A nanoscale computing device in accordance with claim 29, wherein a bias voltage is applied to said substrate during operation of said device.

32. A nanoscale computing device in accordance with claim 20, wherein said electrodes are spaced approximately 5 μm apart.

33. A nanoscale computing device in accordance with claim 20, further comprising at least one additional pair of spaced-apart electrodes carried on said substrate, wherein each pair of electrodes is spaced from between 0.001 and 100 μm from a neighboring pair of electrodes.

34. A nanoscale computing device in accordance with claim 20, wherein said programmable conductive pathway is programmable from a substantially conductive state to a substantially non-conductive state.

35. A nanoscale computing device in accordance with claim 29, wherein said programmable conductive pathway is programmable from a substantially conductive state to a substantially non-conductive state by means of application of at least one voltage pulse of predetermined magnitude across said pair of electrodes.

36. A nanoscale computing device in accordance with claim 20, wherein said programmable conductive pathway is programmable from a state exhibiting a first characteristic I(V) profile to a state exhibiting a second characteristic I(V) profile.

37. A nanoscale computing device in accordance with claim 31, wherein said first characteristic I(V) profile is substantially linear.

38. A nanoscale computing device in accordance with claim 32, wherein said second characteristic I(V) profile is not substantially linear.

39. A nanoscale computing device, comprising:
a substrate;
a discontinuous film of conductive material disposed on said substrate
a pair of conductive input/output electrodes carried on said substrate and disposed in spaced-apart relationship, each of said electrodes being in conductive contact with said discontinuous film of conductive material.

40. A nanoscale computing device in accordance with claim 39, wherein said substrate is formed of a semiconductive material.

41. A nanoscale computing device in accordance with claim 40, wherein said semiconductive material is Si/SiO₂.

42. A nanoscale computing device in accordance with claim 40, wherein a bias voltage is applied to said substrate during operation of said device.

43. A nanoscale computing device in accordance with claim 39, wherein said electrodes are spaced approximately 5 μm apart.

44. A nanoscale computing device in accordance with claim 39, further comprising at least one additional pair of spaced-apart electrodes carried on said substrate, wherein each pair of electrodes is spaced from between 5 and 100 μm from a neighboring pair of electrodes.

45. A nanoscale computing device in accordance with claim 39, wherein said programmable conductive pathway is programmable from a substantially conductive state to a substantially non-conductive state.

46. A nanoscale computing device in accordance with claim 45, wherein said programmable conductive pathway is programmable from a substantially conductive state to a substantially non-conductive state by means of application of at least one voltage pulse of predetermined magnitude across said pair of electrodes.

47. A nanoscale computing device in accordance with claim 39, wherein said programmable conductive pathway is programmable from a state exhibiting a first characteristic I(V) profile to a state exhibiting a second characteristic I(V) profile.

48. A nanoscale computing device in accordance with claim 47, wherein said first characteristic I(V) profile is substantially linear.

49. A nanoscale computing device in accordance with claim 48, wherein said second characteristic I(V) profile is not substantially linear.

50. A nanoscale computing device, comprising:
a substrate;
a discontinuous film of conductive material disposed upon said substrate;
a pair of conductive input/output electrodes carried on said substrate and disposed in spaced-apart relationship;
a substantially disordered assembly of nanowires formed on said substrate in a region between said electrodes, thereby forming at least one programmable conductive pathway between said pair of electrodes.

51. A nanoscale computing device in accordance with claim 50, wherein said nanowires are molecularly encapsulated.

52. A nanoscale computing device in accordance with claim 51, wherein said nanowires comprise gold nanorods.

53. A nanoscale computing device in accordance with claim 50, wherein said nanowires comprise single-wall carbon nanotubes.

54. A nanoscale computing device in accordance with claim 53, wherein said single-wall carbon nanotubes are at least partially encapsulated in gold prior to being molecularly encapsulated.

55. A nanoscale computing device in accordance with claim 51, wherein said nanowires comprise refractory metal wires.

56. A nanoscale computing device in accordance with claim 51, wherein said nanowires comprise semiconductive material.

57. A nanoscale computing device in accordance with claim 51, wherein said nanowires are substantially elongate.

58. A nanoscale computing device in accordance with claim 57, wherein said nanowires are approximately 1-50 nm in diameter and approximately 30-2000 nm long.

59. A nanoscale computing device in accordance with claim 50, wherein said substrate is formed of a semiconductive material.

60. A nanoscale computing device in accordance with claim 59, wherein said semiconductive material is Si/SiO₂.

61. A nanoscale computing device in accordance with claim 59, wherein a bias voltage is applied to said substrate during operation of said device.

62. A nanoscale computing device in accordance with claim 50, wherein said electrodes is spaced approximately 5 μm apart.

63. A nanoscale computing device in accordance with claim 50, further comprising at least one additional pair of spaced-apart electrodes carried on said substrate, wherein each pair of electrodes is spaced from between 0.001 and 100 μm from a neighboring pair of electrodes.

64. A nanoscale computing device in accordance with claim 50, wherein said programmable conductive pathway is programmable from a substantially conductive state to a substantially non-conductive state.

65. A nanoscale computing device in accordance with claim 64, wherein said programmable conductive pathway is programmable from a substantially conductive state to a substantially non-conductive state by means of application of at least one voltage pulse of predetermined magnitude across said pair of electrodes.

66. A nanoscale computing device in accordance with claim 50, wherein said programmable conductive pathway is programmable from a state exhibiting a first characteristic I(V) profile to a state exhibiting a second characteristic I(V) profile.

67. A nanoscale computing device in accordance with claim 66, wherein said first characteristic I(V) profile is substantially linear.

68. A nanoscale computing device in accordance with claim 67, wherein said second characteristic I(V) profile is not substantially linear.

69. A molecular computing device in accordance with claim 50, wherein said discontinuous film of conductive material comprises a discontinuous film of gold.

70. A molecular computing device in accordance with claim 50, wherein said nanowires comprise single-wall carbon nanotubes.

71. A molecular computing device in accordance with claim 50, wherein a state of electrical conduction between one of said at least one pair of input/output electrodes is characterized by an I(V) profile exhibiting a macroscopically discernable variation as operational voltages are applied.

72. A molecular computing device in accordance with claim 71, wherein said state of electrical conduction is subject to change by application of one or more programming voltages to at least one of said input/output electrodes.

73. A method of forming a nanoscale computing device, comprising:
providing a substrate;
forming a pair of juxtaposed, spaced-apart electrodes on said substrate;
applying a substantially disordered assembly of nanowires on said substrate in a central region between said spaced-apart pair of electrodes to form a programmable conductive path between said pair of electrodes.

74. A method in accordance with claim 73, wherein said nanowires are molecularly encapsulated.

75. A method in accordance with claim 74, wherein said nanowires comprise gold nanorods.

76. A method in accordance with claim 74, wherein said nanowires comprise single-wall carbon nanotubes.

77. A method in accordance with claim 76, wherein said single-wall carbon nanotubes are at least partially encapsulated in gold prior to being molecularly encapsulated.

78. A method in accordance with claim 76, wherein said nanowires comprise refractory metal wires.

79. A method in accordance with claim 76, wherein said nanowires comprise semiconductive material.

80. A method in accordance with claim 76, wherein said nanowires are substantially elongate.

81. A method in accordance with claim 80, wherein said nanowires are approximately 1-50 nm in diameter and approximately 30-2000 nm long.

82. A method in accordance with claim 73, wherein said substrate is formed of a semiconductive material.

83. A method in accordance with claim 82, wherein said semiconductive material is Si/SiO₂.

84. A method in accordance with claim 82, wherein a bias voltage is applied to said substrate.

85. A method in accordance with claim 73, wherein said electrodes are spaced approximately 5 μm apart.

86. A method in accordance with claim 73, further comprising at least one additional pair of spaced-apart electrodes carried on said substrate, wherein each pair of electrodes is spaced from between 5 and 100 μm from a neighboring pair of electrodes.

87. A method in accordance with claim 86, wherein said programmable conductive pathway is programmable from a substantially conductive state to a substantially non-conductive state.

88. A method in accordance with claim 87, wherein said programmable conductive pathway is programmable from a substantially conductive state to a substantially non-conductive state by means of application of at least one voltage pulse of predetermined magnitude across said pair of electrodes.

89. A method in accordance with claim 73, wherein said programmable conductive pathway is programmable from a state exhibiting a first characteristic I(V) profile to a state exhibiting a second characteristic I(V) profile.

90. A method in accordance with claim 89, wherein said first characteristic I(V) profile is substantially linear.

91. A method in accordance with claim 90, wherein said second characteristic I(V) profile is not substantially linear.

92. A method of fabricating a nanoscale computing device, comprising:
providing a substrate;
depositing a discontinuous film of conductive material disposed on said substrate;
forming a pair of conductive input/output electrodes carried on said substrate, said electrodes being disposed in spaced-apart relationship, each of said electrodes being in conductive contact with said discontinuous film of conductive material, such that a programmable conductive pathway is formed between said pair of electrodes.

93. A method in accordance with claim 92, wherein said substrate is formed of a semiconductive material.

94. A method in accordance with claim 93, wherein said semiconductive material is Si/SiO₂.

95. A method in accordance with claim 92, wherein said electrodes are spaced approximately 5 μm apart.

96. A method in accordance with claim 95, further comprising at least one additional pair of spaced-apart electrodes carried on said substrate, wherein each pair of electrodes is spaced from between 0.001 and 100 μm from a neighboring pair of electrodes.

97. A method in accordance with claim 92, wherein said programmable conductive pathway is programmable from a substantially conductive state to a substantially non-conductive state.

98. A method in accordance with claim 97, wherein said programmable conductive pathway is programmable from a substantially conductive state to a substantially non-conductive state by means of application of at least one voltage pulse of predetermined magnitude across said pair of electrodes.

99. A method in accordance with claim 92, wherein said programmable conductive pathway is programmable from a state exhibiting a first characteristic I(V) profile to a state exhibiting a second characteristic I(V) profile.

100. A method in accordance with claim 99, wherein said first characteristic I(V) profile is substantially linear.

101. A method in accordance with claim 100, wherein said second characteristic I(V) profile is not substantially linear.

102. A method of forming nanoscale computing device, comprising:
providing a substrate;
depositing a discontinuous film of conductive material disposed upon said substrate;
forming a pair of conductive input/output electrodes carried on said substrate and disposed in spaced-apart relationship;
forming a substantially disordered assembly of nanowires on said substrate in a region between said electrodes, thereby forming at least one programmable conductive pathway between said pair of electrodes.

103. A method in accordance with claim 102, wherein said nanowires are molecularly encapsulated.

104. A method in accordance with claim 103, wherein said nanowires comprise gold nanorods.

105. A method in accordance with claim 104, wherein said nanowires comprise single-wall carbon nanotubes.

106. A method in accordance with claim 105, wherein said single-wall carbon nanotubes are at least partially encapsulated in gold prior to being molecularly encapsulated.

107. A method in accordance with claim 103, wherein said nanowires comprise refractory metal wires.

108. A method in accordance with claim 103, wherein said nanowires comprise semiconductive material.

109. A method in accordance with claim 102, wherein said nanowires are substantially elongate.

110. A method in accordance with claim 109, wherein said nanowires are approximately 1-50 nm in diameter and approximately 30-2000 nm long.

111. A method in accordance with claim 102, wherein said substrate is formed of Si/SiO₂.

112. A method in accordance with claim 102, wherein said electrodes are spaced a approximately 5 μm apart.

113. A method in accordance with claim 102, further comprising providing at least one additional pair of spaced-apart electrodes carried on said substrate, wherein each pair of electrodes is spaced from between 0.001 and 100 μm from a neighboring pair of electrodes.

114. A method in accordance with claim 102, wherein said programmable conductive pathway is programmable from a substantially conductive state to a substantially non-conductive state.

115. A method in accordance with claim 114, wherein said programmable conductive pathway is programmable from a substantially conductive state to a substantially non-conductive state by means of application of at least one voltage pulse of predetermined magnitude across said pair of electrodes.

116. A method in accordance with claim 102, wherein said programmable conductive pathway is programmable from a state exhibiting a first characteristic I(V) profile to a state exhibiting a second characteristic I(V) profile.

117. A method in accordance with claim 116, wherein said first characteristic I(V) profile is substantially linear.

118. A method in accordance with claim 117, wherein said second characteristic I(V) profile is not substantially linear.

119. A method in accordance with claim 102, wherein said discontinuous film of conductive material comprises a discontinuous film of gold.

120. A method in accordance with claim 102, wherein said nanowires comprise single-wall carbon nanotubes.

121. A method in accordance with claim 104, wherein said nanorods are formed of gold.

122. A method in accordance with claim 105, wherein said single-wall nanotubes are between 30 and 2000 nanometers in length and about 1-50 nanometers in diameter.

123. A method in accordance with claim 104, wherein said nanorods are between 30 and 2000 nanometers in length and about 1-50 nanometers in diameter.

124. A method in accordance with claim 102, wherein a state of electrical conduction between one of said at least one pair of input/output electrodes is characterized by an I(V) profile exhibiting a macroscopically discernable variation as operational voltages are applied.

125. A method in accordance with claim 124, wherein said state of electrical conduction is subject to change by application of one or more programming voltages to at least one of said input/output electrodes.

126. A method of operating a nanoscale computing device having a pair of spaced-apart electrodes carried on a substrate upon which a substantially disordered array of nanowires provides a programmable conductive pathway between said pair of electrodes, comprising:
applying a voltage pulse of a first predetermined magnitude across said pair of electrodes to change the I(V) characteristics of said programmable conductive pathway from a first profile to a second profile.

127. A method in accordance with claim 126, wherein said first I(V) profile corresponds to a state of relatively high conductivity between said pair of electrodes and said second I(V) profile corresponds to a state of relatively low conductivity between said pair of electrodes.

128. A method in accordance with claim 127, further comprising:
applying a voltage pulse of a second predetermined magnitude across said pair of electrodes to change the I(V) characteristics of said programmable conductive pathway from said second I(V) profile to said second I(V) profile.

129. A method in accordance with claim 128, wherein said second predetermined magnitude is lower than said first predetermined magnitude.

130. A method in accordance with claim 126, wherein said first I(V) profile is substantially linear.

131. A method in accordance with claim 130, wherein said second I(V) profile is substantially non-linear.
